(19) United States
(12) Patent Application Publication
(10) Pub. No.: US 2019/0143434 A1
(43) Pub. Date: May 16, 2019

(54) Semiconductor Device and Method of Manufacturing Semiconductor Device

(71) Applicant: Mitsubishi Electric Corporation, Tokyo (JP)

(72) Inventors: Yutaka YONEDA, Tokyo (JP); Masao KIKUCHI, Tokyo (JP)

(73) Assignee: Mitsubishi Electric Corporation, Tokyo (JP)

(21) Appl. No.: 16/099,101

(22) PCT Filed: Apr. 27, 2017
(86) PCT No.: PCT/JP2017/016752

§ 371 Date: Nov. 5, 2018

(30) Foreign Application Priority Data
May 11, 2016 (JP) 2016-094983

(51) Int. Cl. B23K 1/00; B23K 1/19; B23K 1/005; H01L 23/49; H01L 23/532; H01L 23/00

(52) U.S. Cl. CPC B23K 1/0016; B23K 1/19; B23K 1/0056; H01L 24/27; H01L 23/53228; H01L 23/53214; H01L 23/49

(57) ABSTRACT

A semiconductor device includes: a semiconductor element; a conductor pattern provided on an insulating substrate and having a main surface to which the semiconductor element is joined; and a terminal electrode joined to the main surface of the conductor pattern by a hard solder material and electrically connected to the semiconductor element. A joining region joined to the hard solder material in the conductor pattern includes: a first region in which the terminal electrode exists in a plan view; and a second region located outside the first region and not overlapping with the terminal electrode. The conductor pattern on the insulating substrate and the terminal electrode can be firmly joined by the hard solder material.

### TECHNICAL FIELD

The present invention relates to a semiconductor device including a semiconductor element and a method of manufacturing the semiconductor device.

### BACKGROUND ART

A semiconductor device is configured in such a manner that a semiconductor element is joined onto a conductor pattern provided on an insulating substrate provided inside a resin case, and an electrode and the conductor pattern on the semiconductor element are joined to a terminal electrode that allows communication between the inside and the outside of the resin case. The portion of the terminal electrode that is exposed to the outside from the resin case forms an electrode terminal or is joined to an electrode terminal separately provided outside the resin case, so as to electrically connect the electrode terminal and an electric circuit external to the semiconductor device, thereby allowing the current to be input and output between the external electric circuit and the semiconductor element. In the case of a power semiconductor device, a high current flows through a joining portion between the terminal electrode and each of the electrode and the conductor pattern on the semiconductor element. Thus, it is necessary to join the terminal electrode and each of the electrode and the conductor pattern on the semiconductor element in a large area so as to reduce the loss caused by the electrical resistance in the joining portion. Accordingly, in the conventional semiconductor device, for joining the terminal electrode and each of the electrode and the conductor pattern on the semiconductor element in a large area, a solder material as a soft solder material made of a tin alloy has been used to cause the melted solder material to wet and spread over the joining surface, thereby achieving joining by brazing.

In the conventional semiconductor device, a laser beam is applied to cause heat to thereby: join an aluminum electrode provided on the semiconductor element and the terminal electrode formed of copper; join the conductor pattern on the insulating substrate having the semiconductor element joined thereto and the terminal electrode; and join the terminal electrode and a copper-made bus bar provided on a housing made of a synthetic resin. A low-melting-point alloy made of tin or made of an tin alloy having a melting point equal to or lower than the melting point of tin (232° C.) is provided between the terminal electrode and the aluminum electrode on the semiconductor element, to which a laser beam is applied while applying pressure from the backside of the joining surface of the terminal electrode. Then, the low-melting-point alloy is melted by conduction of heat from the terminal electrode heated by application of the laser beam, to thereby join the aluminum electrode on the semiconductor element and the terminal electrode in a large area. Furthermore, for joining the terminal electrode and the conductor pattern on the insulating substrate, and for joining the terminal electrode and the bus bar, a laser beam with an energy density increased by light condensing is applied to melt the terminal electrode and the conductor pattern or the bus bar, thereby joining therebetween by spot welding (for example, see PTD 1).

### CITATION LIST

### Patent Document

### PTD 1: Japanese Patent Laying-Open No. 2008-177307

### SUMMARY OF INVENTION

### Technical Problem

There have been increasing cases where semiconductor devices are used at an environmental temperature higher than that in the conventional usage environment. Thus, as disclosed in PTD 1, joining by the solder material as a soft solder material made of tin, a tin alloy or the like cannot sufficiently ensure the reliability of the joining portion in the semiconductor device used at such a high environmental temperature.

Accordingly, the joining portion is joined not by a soft solder material made of a low-melting-point alloy such as a solder material made of tin or a tin alloy, but the conductor pattern on the insulating substrate and the terminal electrode are joined using a hard solder material having a melting temperature equal to or higher than 450° C. Thereby, it is considered that the joining area between the conductor pattern and the terminal electrode is increased to reduce the electrical resistance in the joining portion, so that sufficient reliability can be achieved even during use in a high temperature environment. However, the hard solder material has a high melting temperature, which leads to the following problem. Specifically, brazing using a torch such as a gas burner and furnace brazing using a heating furnace may cause melting of: the solder material used for joining the semiconductor element and the insulating substrate and for jointing a heat dissipation plate and a heat sink; and a resin case of the semiconductor device. Accordingly, it is conceivable to employ a method of using a hard solder material in place of a soft solder material disclosed in PTD 1 to melt the hard solder material through application of a laser beam for brazing.

However, in the case where brazing is performed by heating the hard solder material and the conductor pattern by heat conduction from the terminal electrode heated by application of a laser beam thereto as in the semiconductor device disclosed in PTD 1, the conductor pattern is heated only by heat input from the hard solder material. In addition, the conductor pattern is provided on the high thermal conductive insulating substrate that is joined to a heat dissipation plate or a heat sink serving as a heat dissipation member. Thereby, the temperature of the conductor pattern is less likely to rise as compared with the temperature rise in the terminal electrode, and also, it is difficult to raise the temperature of the conductor pattern to the temperature required for brazing of the hard solder material. As a result, the terminal electrode and the conductor pattern are brazed by a hard solder material in the state where the temperature of the conductor pattern is not sufficiently raised. This causes a problem that the conductor pattern and the terminal electrode cannot be firmly joined to each other.

The present invention has been made in order to solve the above-described problems. An object of the present invention is to provide a semiconductor device in which a conductor pattern on an insulating substrate and a terminal electrode are firmly joined by a hard solder material.

### Solution to Problem

A semiconductor device according to the present invention includes: a semiconductor element; a conductor pattern provided on an insulating substrate and having a main surface to which the semiconductor element is joined; and a terminal electrode joined to the main surface of the conductor pattern by a hard solder material and electrically connected to the semiconductor element. A joining region joined to the hard solder material on the main surface of the conductor pattern includes a first region in which the terminal electrode exists in a plan view, and a second region located outside the first region and not overlapping with the terminal electrode.

Furthermore, a method of manufacturing a semiconductor device according to the present invention includes: a first step of disposing a hard solder material on a main surface of a conductor pattern that is provided on an insulating substrate, a semiconductor element being joined to the main surface; a second step of disposing a terminal electrode on the hard solder material; and a third step of applying a laser beam to the terminal electrode and a surrounding region that is located on the main surface of the conductor pattern and that has the hard solder material disposed thereon, to melt the hard solder material, and join the main surface of the conductor pattern and the terminal electrode by the hard solder material.

### Advantageous Effects of Invention

According to the semiconductor device of the present invention, the joining region between the main surface of the conductor pattern and the hard solder material extends also to the outside of the region in which a terminal electrode exists in a plan view. Thus, it becomes possible to provide a semiconductor device configured such that the main surface of the conductor pattern and the terminal electrode are firmly joined by a hard solder material.

Furthermore, according to the method of manufacturing a semiconductor device of the present invention, the temperature of the terminal electrode and the temperature of the conductor pattern around the region having a hard solder material disposed thereon can be greatly increased, and also, the melted hard solder material can be caused to wet and spread over the main surface of the conductor pattern. Thus, it becomes possible to provide a method of manufacturing a semiconductor device configured such that the main surface of the conductor pattern and the terminal electrode are firmly joined by a hard solder material.

### BRIEF DESCRIPTION OF DRAWINGS

FIG. 1 is a cross-sectional view and a plan view showing a semiconductor device in the first embodiment of the present invention.

FIG. 2 is an enlarged cross-sectional view showing the configuration of a joining portion between the first interconnection and the second interconnection of the semiconductor device in the first embodiment of the present invention.

FIG. 3 is a diagram showing a method of manufacturing a semiconductor device in the first embodiment of the present invention.

FIG. 4 is a diagram showing the method of manufacturing a semiconductor device in the first embodiment of the present invention.

FIG. 5 is a cross-sectional view showing a method of manufacturing a semiconductor device illustrated as a comparative example.

FIG. 6 is a cross-sectional view showing a method of manufacturing another semiconductor device in the first embodiment of the present invention.

FIG. 7 is a diagram showing an experimental result obtained when the terminal electrode of the semiconductor device in the first embodiment of the present invention is joined by a hard solder material.

FIG. 8 is a partial cross-sectional view and a partial plan view showing another configuration of the semiconductor device in the first embodiment of the present invention.

FIG. 9 is a partial plan view showing another configuration of the semiconductor device in the first embodiment of the present invention.

FIG. 10 is a partial enlarged view showing a partial configuration of the semiconductor device having another configuration in the first embodiment of the present invention.

FIG. 11 is a partial enlarged view showing a partial configuration of the semiconductor device having another configuration in the first embodiment of the present invention.

FIG. 12 is a partial enlarged view showing a partial configuration of the semiconductor device having another configuration in the first embodiment of the present invention.

FIG. 13 is a cross-sectional view and a plan view showing a method of manufacturing a semiconductor device in the second embodiment of the present invention.

FIG. 14 is a partial cross-sectional view and a partial plan view showing a method of manufacturing a semiconductor device having another configuration in the second embodiment of the present invention.

FIG. 15 is a partial cross-sectional view and a partial plan view showing the method of manufacturing a semiconductor device having another configuration in the second embodiment of the present invention.

FIG. 16 is a partial cross-sectional view and a partial plan view showing the method of manufacturing a semiconductor device having another configuration in the second embodiment of the present invention.

FIG. 17 is a partial cross-sectional view and a partial plan view showing the method of manufacturing a semiconductor device having another configuration in the second embodiment of the present invention.

### DESCRIPTION OF EMBODIMENTS

### First Embodiment

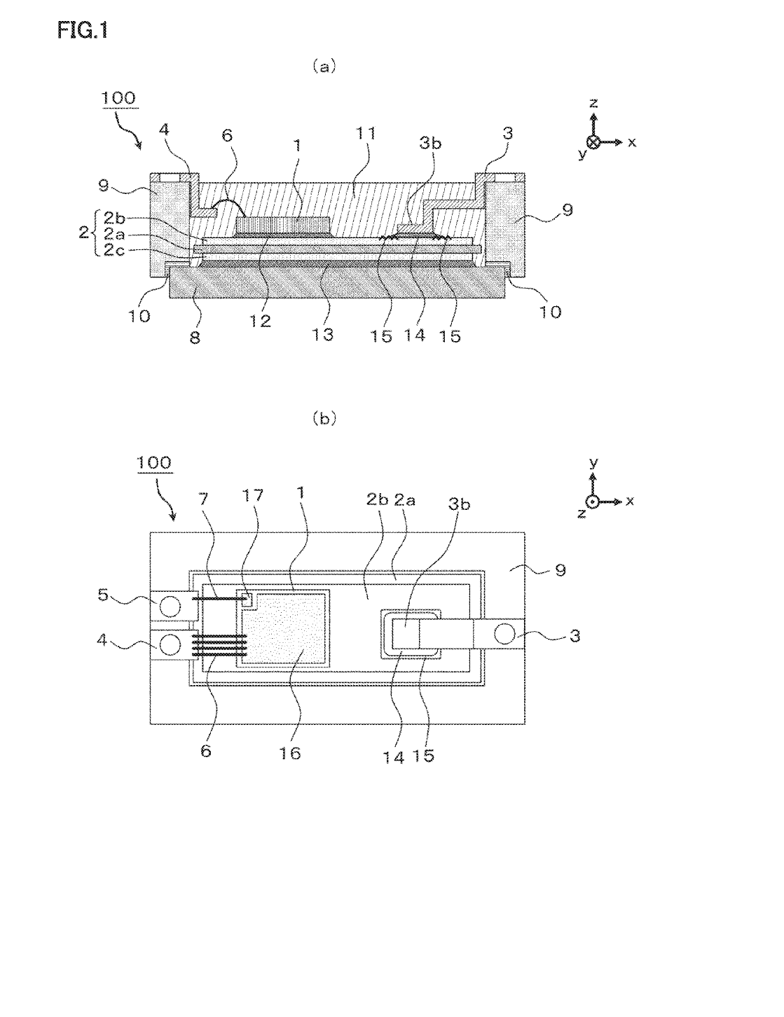

First, the configuration of a semiconductor device in the first embodiment of the present invention will be hereinafter described. FIG. 1 is a cross-sectional view and a plan view showing a semiconductor device in the first embodiment of the present invention. FIG. 1(a) is a cross-sectional view showing the configuration of a semiconductor device 100, and FIG. 1(b) is a plan view showing the configuration of semiconductor device 100. The figure also shows XYZ rectangular coordinates axes. In FIG. 1(b), a sealing resin 11 is not shown for the sake of clarification of the configuration inside semiconductor device 100.

In FIG. 1, semiconductor device 100 includes: a semiconductor element 1; an insulating substrate 2 to which semiconductor element 1 is joined; a terminal electrode 3, a terminal electrode 4 and a terminal electrode 5 each serving as an interconnection for electrically connecting semiconductor element 1 and an electric circuit external to semiconductor device 100; and a heat dissipation plate 8 configured to dissipate the heat of semiconductor element 1. These elements are disposed inside a resin case 9 and sealed with a sealing resin 11.

Semiconductor element 1 is a power semiconductor element such as an insulated gate bipolar transistor (IGBT) and a metal-oxide-semiconductor field-effect transistor (MOSFET), and formed of a semiconductor material such as silicon (Si), silicon carbide (SiC) or gallium nitride (GaN). The following is an explanation about the case where semiconductor element 1 is a MOSEFT formed of silicon carbide (which will be hereinafter referred to as an SiC MOSFET), but semiconductor element 1 may be an IGBT or may be an IGBT or a MOSFET that is formed of other semiconductor materials such as silicon.

Semiconductor element 1 is formed in a vertical-structure. Semiconductor element 1 has a lower surface on which a drain electrode is provided, and an upper surface on which a source electrode 16 and a gate electrode 17 are provided. The drain electrode of semiconductor element 1 and the main surface of conductor pattern 2b as the first interconnection provided on insulating substrate 2 are joined to each other by a joining material 12 such as a solder material made of a soft solder material. The drain electrode and source electrode 16 serve as main electrodes through which a main current supplied from an electric circuit external to semiconductor device 100 flows. Gate electrode 17 serves as a control electrode: to which a control voltage is applied from a control circuit on the outside or inside of semiconductor device 100; and through which a control current supplied from the control circuit flows. In power semiconductor device 100, the main current may reach a magnitude equal to or greater than several ten amperes while the control current has a maximum value equal to or less than several amperes, and has an average value equal to or less than 1 ampere.

Insulating substrate 2 includes a ceramic plate 2a as an insulation substrate having a high thermal conductivity and made of aluminum nitride (MN), silicon nitride (Si₃N₄), alumina (Al₂O₃), or the like. Ceramic plate 2a has both surfaces on which a conductor pattern 2b and a conductor pattern 2c are formed, each of which is formed of a metal material such as copper (Cu) or aluminum (Al) with high electric conductivity. Conductor pattern 2b and conductor pattern 2c are joined to ceramic plate 2a by the method such as brazing, thereby forming insulating substrate 2. It is preferable that conductor pattern 2b and conductor pattern 2c are formed of the same metal material for the purpose of reducing the manufacturing cost. Ceramic plate 2a may have a thickness of 0.635 mm or 0.32 mm, for example. Conductor patterns 2b and 2c each may have a thickness equal to or less than 1 mm, for example. In the present invention, the surfaces of conductor pattern 2b and conductor pattern 2c on the opposite side of the surfaces joined to ceramic plate 2a will be referred to as a main surface of conductor pattern 2b and a main surface of conductor pattern 2c, respectively.

The main surface of conductor pattern 2c provided on insulating substrate 2 and heat dissipation plate 8 are joined by a joining material 13 such as a solder material made of a soft solder material, so that insulating substrate 2 is fixed to heat dissipation plate 8. Not only one insulating substrate 2 as shown in FIG. 1 but also a plurality of insulating substrates may be joined onto heat dissipation plate 8. Heat dissipation plate 8 is formed of a material with high thermal conductivity such as a metal plate made of copper (Cu), aluminum (Al) or the like and an aluminum silicon carbide composite (AlSiC). Heat dissipation plate 8 has a thickness of 1 mm to 5 mm. The surface of heat dissipation plate 8 on the opposite side of the surface joined to insulating substrate 2 is joined to a heat sink (not shown) by heat dissipation grease or the like. The heat generated by semiconductor element 1 and the like joined onto insulating substrate 2 reaches heat dissipation plate 8 through insulating substrate 2 with high thermal conductivity. Then, the heat is diffused by heat dissipation plate 8 in the plane direction, and transferred to the heat sink and dissipated to the outside of semiconductor device 100.

Joining material 13 joining insulating substrate 2 and heat dissipation plate 8 is preferably formed of a metal material with high thermal conductivity in order to efficiently transfer the heat from insulating substrate 2 to heat dissipation plate 8, and also preferably formed of a soft solder material made of tin (Sn), silver (Ag), copper (Cu) or the like and having a melting temperature less than 450° C., that is, a solder material. It is preferable that joining material 13 is formed to have a thickness of 0.1 mm to 0.3 mm for the purpose of achieving both reliability and heat dissipation performance. Furthermore, joining material 12 may also be formed of the same solder material as that of joining material 13.

In the description of the present invention, the temperature at which a solid such as metal melts is referred to as a melting temperature. The melting temperature used in the present invention means a temperature at which a solid starts to melt when the temperature of the solid is raised. When the solid is pure metal, its melting point is a melting temperature. When the solid is an alloy, its solid phase temperature is a melting temperature. In other words, when the temperature of the solid becomes equal to or higher than the melting temperature, it becomes difficult for the solid to keep its shape, so that sufficient strength as a solid cannot be obtained. Also, even when the solid is made of a resin, it becomes difficult for the solid to keep its shape at a melting temperature or higher, so that sufficient strength as a solid cannot be obtained.

Resin case 9 is bonded to heat dissipation plate 8 by an adhesive 10 so as to surround insulating substrate 2 joined to heat dissipation plate 8. Resin case 9 may be made of a thermoplastic resin such as polybutylene terephthalate (PBT) and polyphenylene sulfide (PPS) each of which has a melting temperature equal to or lower than 300° C., for example. Adhesive 10 may be made of an epoxy-based thermosetting resin, for example.

Terminal electrode 3, terminal electrode 4 and terminal electrode 5 serving as the second interconnections each have one end that is attached to resin case 9 so as to be exposed to the outside of semiconductor device 100. One end of each of terminal electrode 3, terminal electrode 4 and terminal electrode 5 that is exposed to the outside of semiconductor device 100 forms an electrode terminal to be connected to the electric circuit external to semiconductor device 100. Terminal electrode 3, terminal electrode 4 and terminal electrode 5 each serve as an interconnection for electrically connecting semiconductor element 1 and the external electric circuit. Thus, terminal electrode 3, terminal electrode 4 and terminal electrode 5 each are preferably made of a metal material with high electric conductivity such as copper or aluminum, and formed by cutting or press-working a copper plate or an aluminum plate.

Terminal electrode 4 is electrically connected to source electrode 16 of semiconductor element 1 through a metal wire 6 such as an aluminum wire or a gold wire by ultrasonic joining or the like with a wire bonding apparatus. Terminal electrode 5 is connected to gate electrode 17 of semiconductor element 1 by a metal wire 7. Since a high current flows between terminal electrode 4 and source electrode 16, a plurality of metal wires 6 are provided.

By a hard solder material 14 formed of a metal material having a melting temperature equal to or higher than 450° C., the other end of terminal electrode 3 on the opposite side of one end attached to resin case 9 is joined to the main surface of conductor pattern 2b on insulating substrate 2, onto which the drain electrode of semiconductor element 1 is joined. Consequently, the drain electrode of semiconductor element 1 and the external electric circuit connected to the electrode terminal provided in terminal electrode 3 are electrically connected to each other through conductor pattern 2b and terminal electrode 3.

Hard solder material 14 serves as: a heat transfer path through which the Joule heat generated by an electrical resistance in terminal electrode 3 is dissipated through insulating substrate 2 and heat dissipation plate 8 to the outside of semiconductor device 100 upon flowing of a high current through terminal electrode 3; and also serves as an electric conductive path for electrically connecting conductor pattern 2b and terminal electrode 3. Accordingly, it is preferable that hard solder material 14 is made of a metal material having a high melting temperature, high thermal conductivity and high electric conductivity, so that a hard solder material having a melting temperature equal to or higher than 450° C. is used in place of a soft solder material. Thereby, the reliability of joining between conductor pattern 2b and terminal electrode 3 can be sufficiently increased even when semiconductor device 100 is used at a high environmental temperature.

It is suitable to form hard solder material 14 from copper phosphorus brazing filler metal, brass brazing filler metal, phosphor bronze brazing filler metal, copper brazing filler metal, silver brazing filler metal, gold brazing filler metal, aluminum brazing filler metal, nickel brazing filler metal, and the like. Particularly, when conductor pattern 2b and terminal electrode 3 are formed of copper, it is preferable that copper phosphorous (Cu—Ag—P) brazing filler metal having a melting temperature of about 650° C. to about 700° C. and a brazing temperature of about 800° C. is used as hard solder material 14 since conductor pattern 2b and terminal electrode 3 can be brazed without using a flux. Furthermore, hard solder material 14 is preferably less in thickness in order to improve the reliability, and is preferably equal to or less than 0.25 mm, for example.

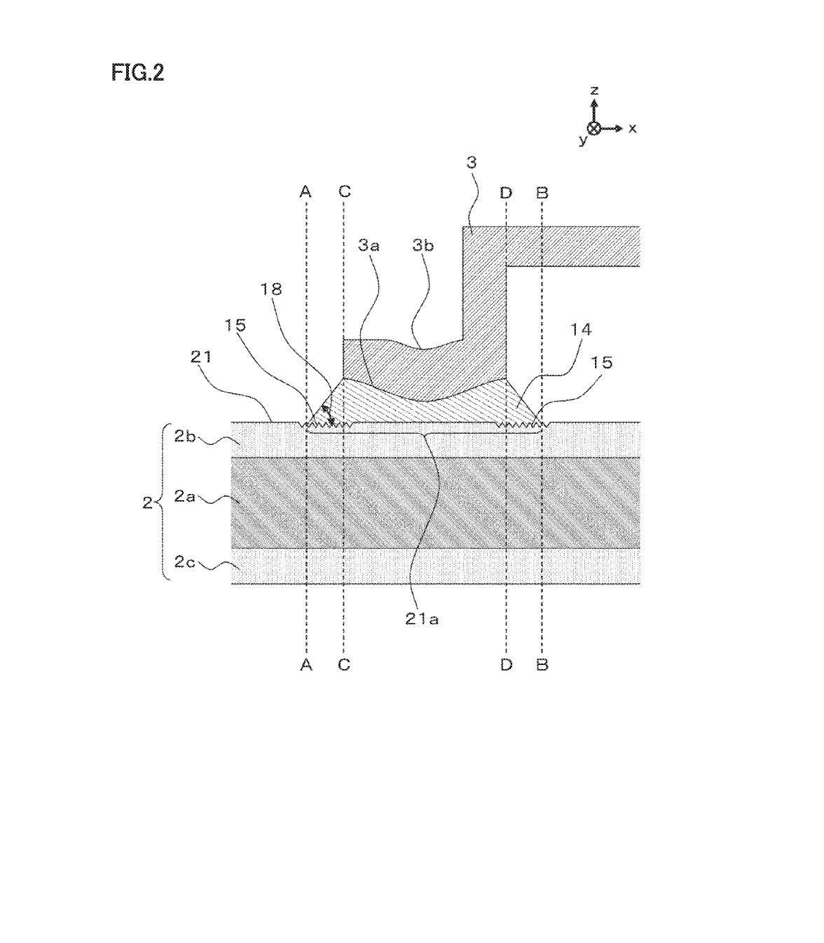

The configuration of the joining portion between conductor pattern 2b and terminal electrode 3 will be hereinafter more specifically described. FIG. 2 is an enlarged cross-sectional view showing the configuration of the joining portion between the conductor pattern and the terminal electrode in the semiconductor device in the first embodiment of the present invention. FIG. 2 is an enlarged view showing the configuration of the joining portion at which conductor pattern 2b on insulating substrate 2 and terminal electrode 3 are joined by hard solder material 14, which is shown in FIG. 1(a).

As shown in FIG. 2, the region between a dashed line A-A and a dashed line B-B in a plane-shaped main surface 21 of conductor pattern 2b provided on insulating substrate 2 serves as a first joining region 21a where conductor pattern 2b and hard solder material 14 are joined. Furthermore, the region located between a dashed line C-C and a dashed line D-D and serving as a joining surface between terminal electrode 3 and hard solder material 14 corresponds to a second joining region 3a where terminal electrode 3 and hard solder material 14 are joined. In this case, the above-mentioned joining surface between terminal electrode 3 and hard solder material 14 corresponds to one surface of terminal electrode 3 that is formed by bending the end of terminal electrode 3 made of a belt-like metal plate so as to face first joining region 21a. In other words, the peripheral edge of the joining surface of terminal electrode 3 corresponds to the peripheral edge of the second joining region.

In FIG. 2, the width of first joining region 21a is greater than the width of second joining region 3a in the X-axis direction while the width of first joining region 21a is greater than the width of second joining region 3a also in the Y-axis direction. In other words, second joining region 3a is included in first joining region 21a in a plan view seen from the top toward the bottom along the Z-axis on the sheet of paper showing the figure. Also, second joining region 3a is provided on the inner side of the peripheral edge of first joining region 21a. Furthermore, first joining region 21a located in conductor pattern 2b and serving as a joining region joined to hard solder material 14 includes: the first region in which terminal electrode 3 exists in a plan view; and the second region located outside the first region and not overlapping with the terminal electrode. In FIG. 2, the region included in first joining region 21a and located between dashed line C-C and dashed line D-D is the first region. Also, the region between dashed line A-A and dashed line C-C and the region between dashed line B-B and dashed line D-D each are the second region.

The second region included in first joining region 21a provided in conductor pattern 2b is provided with a roughened region 15 that is formed by subjecting main surface 21 of conductor pattern 2b to a roughening treatment. The value of a surface roughness Ra of roughened region 15 is greater than the value of surface roughness Ra of main surface 21 in the portion of conductor pattern 2b where roughened region 15 is not provided. Specifically, roughened region 15 is greater in surface roughness than at least a part of the region on the outside of first joining region 21a serving as the joining region in which conductor pattern 2b and hard solder material 14 are joined. At least a part of the region on the outside of first joining region 21a may, for example, be a region in which semiconductor element 1 is joined to conductor pattern 2b by a soft solder material and a region therearound. The roughening treatment for forming roughened region 15 may be sand blasting, etching, and the like, for example.

As shown in FIG. 2, in a plan view seen from the top toward the bottom along the Z-axis on the sheet of paper showing the figure, roughened region 15 is provided in a region on the outside of the peripheral edge of second joining region 3a, that is, in a region between dashed line A-A and dashed line C-C and a region between dashed line B-B and dashed line D-D. In other words, roughened region 15 is provided in the second region included in first joining region 21a. Furthermore, a part of roughened region 15 is provided also in the first region included in first joining region 21a and located between dashed line C-C and dashed line D-D, that is, provided on the inner side of the peripheral edge of second joining region 3a in a plan view. Similarly, a part of roughened region 15 is provided also on the outside of first joining region 21a between dashed line A-A and dashed line B-B. Namely, at least a part of roughened region 15 may be provided inside first joining region 21a and outside the peripheral edge of second joining region 3a in a plan view. In other words, at least a part of roughened region 15 is provided in the second region included in first joining region 21a and located on the outside of the region where terminal electrode 3 exists in a plan view.

Between first joining region 21a and second joining region 3a, hard solder material 14 formed of a metal material having a melting temperature equal to or higher than 450° C. is provided. The first joining region of conductor pattern 2b and second joining region 3a of terminal electrode 3 are joined through brazing by hard solder material 14. Accordingly, the melting temperature of the metal material forming hard solder material 14 is lower than the melting temperature of the first metal material forming conductor pattern 2b, and is lower than the melting temperature of the second metal material forming terminal electrode 3.

Hard solder material 14 is provided on first joining region 21a at a contact angle 18 less than 90° with respect to main surface 21 of conductor pattern 2b. When first joining region 21a and second joining region 3a are joined, the hard solder material is melted and liquefied. Contact angle 18 varies in accordance with the wettability of this liquefied hard solder material to first joining region 21a. When the wettability is excellent, contact angle 18 is less than 90°. At contact angle 18 less than 90°, first joining region 21a and second joining region 3a can be firmly joined.

Also as shown in FIG. 2, it is preferable that second joining region 3a has a shape protruding toward first joining region 21a. In other words, it is preferable that the surface of terminal electrode 3, which has second joining region 3a provided thereon and which is joined to hard solder material 14, has a convex surface. When second joining region 3a has a shape protruding toward first joining region 21a, the hard solder material melted and liquefied during joining between first joining region 21a and second joining region 3a is more likely to wet the peripheral edge of first joining region 21a and spread in the direction thereof. Thereby, contact angle 18 can be further reduced. However, second joining region 3a may have a flat shape that is approximately in parallel with main surface 21 of conductor pattern 2b. In other words, the surface of terminal electrode 3 where second joining region 3a is provided may be a flat surface. The width of the second joining region, that is, the distance between dashed line C-C and dashed line D-D, may be 2 mm to 6 mm, for example. The surface of terminal electrode 3 on the back side of second joining region 3a corresponds to a heating surface 3b for heating terminal electrode 3 when first joining region 21a and second joining region 3a are joined. It is preferable that the value of surface roughness Ra of roughened region 15 is greater than the value of surface roughness Ra of heating surface 3b.

Then, as shown in FIG. 1(a), resin case 9 is sealed with sealing resin 11 to form semiconductor device 100. Sealing resin 11 may be an epoxy resin or a silicon resin, for example. Furthermore, a silicon gel may be introduced into resin case 9 and the opening of resin case 9 may be closed by an upper cover, thereby sealing resin case 9.

Then, the method of manufacturing semiconductor device 100 will be hereinafter described.

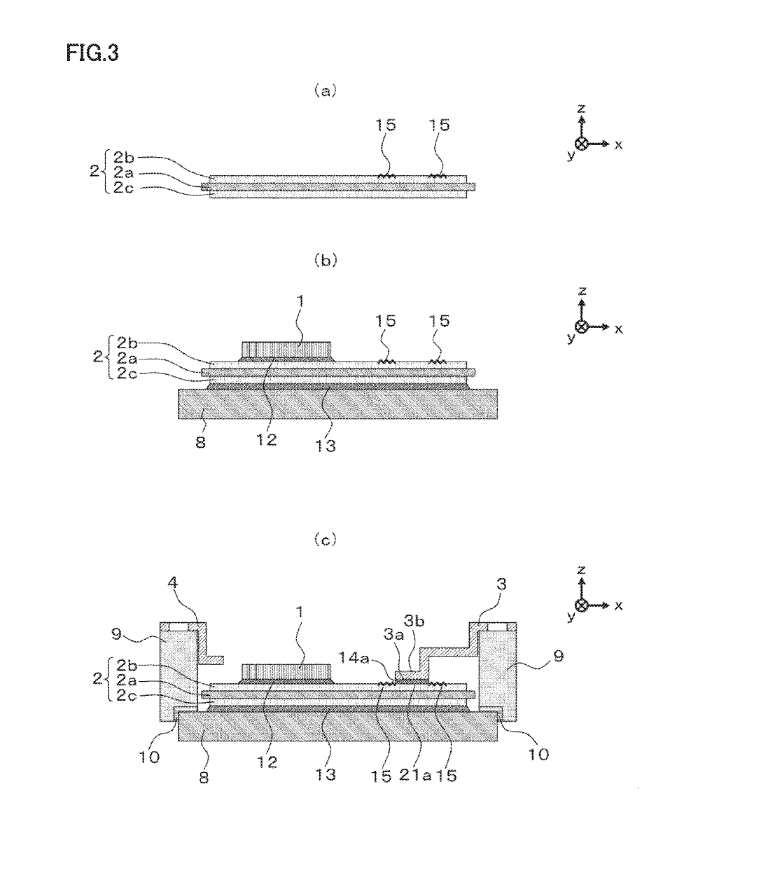

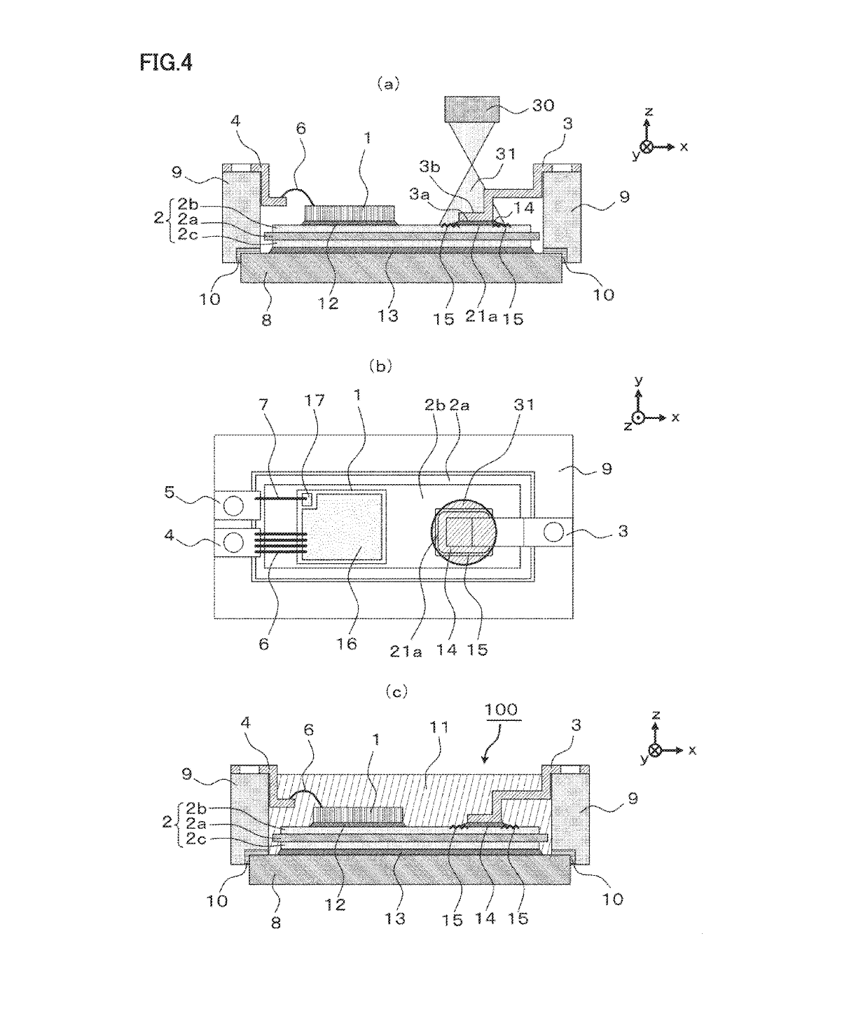

FIGS. 3 and 4 each are a diagram showing a method of manufacturing a semiconductor device in the first embodiment of the present invention. FIG. 3 is a cross-sectional view showing the process from the step forming roughened region 15 in the first joining region to the step of disposing sheet-shaped hard solder material 14a before joining between the first joining region and the second joining region. FIG. 4 is a cross-sectional view and a plan view showing the step of melting the hard solder material by applying a laser beam to the joining portion, and a cross-sectional view showing the step of completing semiconductor device 100.

First, roughened region 15 is formed in conductor pattern 2b provided on insulating substrate 2 as shown in FIG. 3(a). Conductor pattern 2b serves as an interconnection between semiconductor element 1 and terminal electrode 3 joined to conductor pattern 2b. On the copper plate or the like joined to ceramic plate 2a, etching or the like is conducted to thereby form an interconnection pattern for joining semiconductor element 1, and an interconnection pattern on which the first joining region is provided. Then, by a photoresist, a portion where roughened region 15 is to be formed is opened and masked, which is then subjected to sand blasting or etching, thereby forming roughened region 15 as shown in FIG. 3(a). When surface roughness Ra of terminal electrode 3 is 0.05 μm to 0.2 μm, surface roughness Ra of roughened region 15 is preferably 1 μm to 100 μm. In this case, surface roughness Ra is a center line average roughness defined by JIS B0601 and is defined as a value obtained by dividing, by the measurement length, the area obtained from the center line and the roughness curve that is folded along the center line.

Furthermore, roughened region 15 is formed to have a width equal to or greater than a prescribed value along the peripheral edge of second joining region 3a. It is preferable that the width of roughened region 15 along the peripheral edge of second joining region 3a shows a value equal to or greater than half of the thickness of terminal electrode 3 so as to provide a fillet having contact angle 18 shown in FIG. 2 less than 90° even when hard solder material 14 melts to wet and spread over the side surface of terminal electrode 3 to about half of the thickness of terminal electrode 3. Furthermore, it is more preferable that the width of roughened region 15 along the peripheral edge of second joining region 3a shows a value equal to or greater than the thickness of terminal electrode 3 so as to provide a fillet having contact angle 18 shown in FIG. 2 less than 90° even when hard solder material 14 melts to wet and spread over the entire side surface of terminal electrode 3. Specifically, when the thickness of terminal electrode 3 is 1 mm, it is preferable that roughened region 15 is formed on the outside of the peripheral edge of second joining region 3a along this peripheral edge so as to have a width equal to or greater than 0.5 mm, and more preferable that roughened region 15 is formed to have a width equal to or greater than 1 mm.

Then, as shown in FIG. 3(b), insulating substrate 2 in which roughened region 15 is formed inside the first joining region of conductor pattern 2b is joined to heat dissipation plate 8 and semiconductor element 1. First, heat dissipation plate 8 is placed on a heating apparatus such as a hot plate. Joining material 13 such as a solder sheet is disposed on heat dissipation plate 8. Then, insulating substrate 2 is disposed on joining material 13 such that conductor pattern 2c comes in contact with joining material 13. Then, joining material 12 such as a solder sheet is disposed in the joining region provided in conductor pattern 2b on insulating substrate 2 and to be joined to semiconductor element 1. The drain electrode of semiconductor element 1 is disposed on joining material 12 so as to contact joining material 12.

In this way, after heat dissipation plate 8, joining material 13, insulating substrate 2, joining material 12, and semiconductor element 1 are stacked on top of one another, the temperature of the hot plate is raised to heat the heat dissipation plate 8. Consequently, the heat from the hot plate is transferred through heat dissipation plate 8 and insulating substrate 2 to joining material 13 and joining material 12, thereby melting joining material 13 and joining material 12. When joining material 13 and joining material 12 are sufficiently heated and melted, joining material 13 wets and spreads over heat dissipation plate 8, and joining material 12 wets and spreads over conductor pattern 2b, then, heating by the hot plate is stopped. Then, the temperatures of melted joining material 13 and melted joining material 12 lower to their respective melting temperatures or lower, so that joining material 13 and joining material 12 are solidified. Consequently, heat dissipation plate 8 and conductor pattern 2c are soldered to each other, and conductor pattern 2b and semiconductor element 1 are soldered to each other. In this case, heating by a hot plate has been described, but heating may be carried out by other methods using a reflow furnace or the like after heat dissipation plate 8, joining material 13, insulating substrate 2, joining material 12, and semiconductor element 1 are stacked on top of one another.

Then, as shown in FIG. 3(c), sheet-shaped hard solder material 14a is disposed between first joining region 21a of conductor pattern 2b and second joining region 3a of terminal electrode 3. Then, resin case 9 is bonded to heat dissipation plate 8 with adhesive 10. Resin case 9 is equipped in advance with terminal electrode 3, terminal electrode 4 and terminal electrode 5, each of which is formed by press-working a metal plate made of copper or the like. When resin case 9 is disposed at a prescribed position with respect to heat dissipation plate 8, terminal electrode 3 is attached to resin case 9 such that second joining region 3a is included in a plan view in first joining region 21a provided in conductor pattern 2b.

First, sheet-shaped hard solder material 14a is disposed on first joining region 21a provided in conductor pattern 2b so as to expose roughened region 15 formed inside first joining region 21a in a plan view in the Z-axis direction. When conductor pattern 2b is made of copper and sheet-shaped hard solder material 14a is made of copper phosphorus brazing filler metal, sheet-shaped hard solder material 14a may be directly disposed on first joining region 21a. However, when conductor pattern 2b is not made of copper but made of a copper alloy, aluminum or the like, and when the sheet-shaped hard solder material is not made of copper phosphorus brazing filler metal, a flux may be provided between first joining region 21a and sheet-shaped hard solder material 14a.

Then, adhesive 10 made of an epoxy-based thermosetting resin is applied above and around heat dissipation plate 8, and resin case 9 is disposed at a prescribed position with respect to heat dissipation plate 8. Thereby, terminal electrode 3 is disposed on sheet-shaped hard solder material 14a such that second joining region 3a is included in first joining region 21a in a plan view in the Z-axis direction and that roughened region 15 formed inside first joining region 21a is exposed. When sheet-shaped hard solder material 14a is made of copper phosphorus brazing filler metal and when terminal electrode 3 is made of copper, second joining region 3a may be directly disposed on sheet-shaped hard solder material 14a. However, when sheet-shaped hard solder material 14a is not made of copper phosphorus brazing filler metal and when the terminal electrode is not made of copper but made of a copper alloy, aluminum or the like, a flux may be provided between sheet-shaped hard solder material 14a and second joining region 3a. Then, adhesive 10 is heated by a hot plate or the like that is disposed below heat dissipation plate 8, and thereby thermally hardened, so that heat dissipation plate 8 and resin case 9 are fixedly bonded to each other.

In addition, terminal electrode 3 may be disposed and brazed before resin case 9 is disposed at a prescribed position with respect to heat dissipation plate 8. In this case, however, since terminal electrode 3 needs to be fixed to resin case 9, the number of assembly steps is increased. Furthermore, it is also necessary to prepare a jig and the like for causing terminal electrode 3 to independently stand before brazing. Furthermore, it becomes impossible to use resin case 9 having an insert case structure, in which resin case 9 is formed so as to cover a part of terminal electrode 3 to fix terminal electrode 3. Accordingly, it is preferable that resin case 9 to which one end of terminal electrode 3 is fixed is disposed at a prescribed position with respect to heat dissipation plate 8 before brazing since the number of assembly steps can be reduced to thereby reduce the processing cost while increasing alternatives for the structure of resin case 9.

Then, as shown in FIGS. 4(a) and 4(b), a laser beam is applied such that first joining region 21a and second joining region 3a are brazed. FIG. 4(a) is a cross-sectional view showing the step of applying a laser beam for brazing. FIG. 4(b) is a plan view showing the step of applying a laser beam for brazing.

First, by ultrasonic joining using a wire bonding apparatus, source electrode 16 of semiconductor element 1 and terminal electrode 4 are electrically connected by metal wire 6, and gate electrode 17 and terminal electrode 5 are electrically connected by metal wire 7. Connection between source electrode 16 and terminal electrode 4 by metal wire 6, and connection between gate electrode 17 and terminal electrode 5 by metal wire 7 may be established after first joining region 21a and second joining region 3a are joined.

As shown in FIGS. 4(a) and 4(b), a laser beam 31 is applied from a laser apparatus 30 in the state where a sheet-shaped hard solder material is provided between first joining region 21a of conductor pattern 2b and the second joining region of terminal electrode 3. Laser beam 31 is applied to irradiate second joining region 3a in a plan view in the Z-axis direction and also to irradiate roughened region 15 formed inside first joining region 21a in a plan view in the Z-axis direction. In other words, laser beam 31 is applied to a region including: the region in which a sheet-shaped hard solder material is provided in a plan view; and the region of first joining region 21a located outside terminal electrode 3 and not overlapping with terminal electrode 3. Consequently, laser beam 31 is applied to heating surface 3b of terminal electrode 3 and roughened region 15. It is preferable that laser beam 31 is applied to the entire roughened region 15 formed inside first joining region 21a, but may be applied to a part of roughened region 15. It is more preferable that laser beam 31 is applied so as to irradiate first joining region 21a in a plan view in the Z-axis direction. It is preferable that laser beam 31 has a wavelength equal to or greater than 500 nm and equal to or less than 1500 nm.

Examples of laser apparatus 30 configured to output laser beam 31 having such a wavelength may be: a YAG laser and a Yb3 laser each configured to output a laser beam having a wavelength of 1064 nm; a semiconductor laser configured to output a laser beam having a wavelength equal to or less than 980 nm; a YAG laser and a Yb fiber laser each configured to output a laser beam having a wavelength of 532 nm that is an SHG (second harmonic generation:second harmonic wave) having a wavelength of 1064 nm; and the like. Laser apparatus 30 includes an optical system such as a lens, a mirror and the like, which is configured to control light distribution of the laser beam to be output. When a Yb fiber laser (a wavelength of 1064 nm) with a continuous oscillation (CW) output of 2 kW to 3 kW is used as laser apparatus 30, laser beam 31 is emitted for about 1 second to 1.5 seconds, for example.

Since roughened region 15 is exposed in the direction in which laser beam 31 is applied in a plan view in the Z-axis direction, laser beam 31 is applied to heating surface 3b of terminal electrode 3 as well as roughened region 15. Since roughened region 15 is greater in surface roughness than the region of main surface 21 of conductor pattern 2b in which roughened region 15 is not formed, the absorptance of laser beam 31 in roughened region 15 is higher than the absorptance of the laser beam in the region on main surface 21 of conductor pattern 2b in which roughened region 15 is not formed. Consequently, laser beam 31 is more absorbed in roughened region 15 than in the case where a roughened region is not formed inside first joining region 21a. Thus, the amount of heat generated in the portion where roughened region 15 is formed can be increased. Furthermore, when roughened region 15 is greater in surface roughness than heating surface 3b of terminal electrode 3, the temperature rise in first joining region 21a having roughened region 15 provided therein can be increased more than the temperature rise in second joining region 3a provided on the back side of heating surface 3b.

The absorptance of laser beam 31 used herein means the absorptance to the light having the same wavelength as that of laser beam 31, and is identical to the emissivity to the light having the same wavelength as that of laser beam 31. Thus, absorptance may be used synonymously with emissivity. Since emissivity and reflectance may establish a relational expression: emissivity=1−reflectance, there may be also a relation expression: absorptance=1−reflectance. As generally widely known, the emissivity of metal is greater when the surface is roughened than when the surface is smoothed. By way of example, the emissivity of copper to the light having a wavelength of 1 μm is about 5% of emissivity in the case of a smooth surface, but is about 20% of emissivity in the case of a roughened surface inside roughened region 15.

As shown in FIGS. 4(a) and 4(b), when laser beam 31 is applied from terminal electrode 3, laser beam 31 is applied to heating surface 3b provided on the back side of second joining region 3a of terminal electrode 3 and to roughened region 15 formed inside the first joining region. Consequently, the applied laser beam 31 is absorbed by heating surface 3b and roughened region 15, which then generate heat. Through heat conduction, the heat generated from heating surface 3b heats second joining region 3a, and the heat generated from roughened region 15 heats first joining region 21a. Then, heat is conducted through first joining region 21a and second joining region 3a to a sheet-shaped hard solder material, which is raised in temperature to the melting temperature and then melted.

Due to formation of roughened region 15, the absorptance of laser beam 31 in the portion where roughened region 15 is formed is increased. Accordingly, the temperature of first joining region 21a where roughened region 15 is formed reaches the temperature that is enough to allow melted hard solder material 14 to wet and spread over first joining region 21a. Then, melted hard solder material 14 wets and spreads over roughened region 15, which serves as a heat generation source and whose temperature is raised most inside conductor pattern 2b. Furthermore, due to capillarity caused by the concavo-convex structure on roughened region 15, melted hard solder material 14 is further more likely to wet and spread over roughened region 15. Roughened region 15 is formed in the region on the outside of the peripheral edge of second joining region 3a in a plan view in the Z-axis direction. Thus, the wetting angle between first joining region 21a of conductor pattern 2b and the melted hard solder material is less than 90°. Then, melted hard solder material 14 sufficiently wets first joining region 21a and second joining region 3a.

Laser beam 31 is applied for an extremely short period of time. As described above, when a Yb fiber laser with a continuous oscillation output of 2 kW to 3 kW having a wavelength of 1064 nm is used, application of laser beam 31 is stopped after laser beam 31 is applied for about 1 second to 1.5 seconds. Thus, application of laser beam 31 is stopped before the heat generated in roughened region 15 absorbing laser beam 31 is conducted through conductor pattern 2b and insulating substrate 2, and the temperatures in joining material 12 and joining material 13 reach their respective melting temperatures. Accordingly, first joining region 21a of conductor pattern 2b and second joining region 3a of terminal electrode 3 can be brazed by hard solder material 14 without melting joining material 12 and joining material 13. When application of laser beam 31 is stopped, the temperature of hard solder material 14 is lowered, so that hard solder material 14 is solidified. Consequently, as shown in FIG. 2, a fillet having contact angle 18 less than 90° with conductor pattern 2b is formed, and conductor pattern 2b and terminal electrode 3 are brazed by hard solder material 14.

When conductor pattern 2b and terminal electrode 3 each are formed of copper and hard solder material 14 is formed of copper phosphorus brazing filler metal, the surfaces of first joining region 21a and second joining region 3a are reduced by the reducing action of phosphorus (P) contained in copper phosphorus brazing filler metal. Thus, a flux is not longer required. It is preferable that a flux less in thermal conductivity than metal is no longer required, which can increase the heat conduction from first joining region 21a to the sheet-shaped hard solder material and the heat conduction from second joining region 3a to the sheet-shaped hard solder material, so that the temperature of the hard solder material can be further more raised, with the result that the wettability between the melted hard solder material and each of first joining region 21a and second joining region 3a can be further improved.

Then, as shown in FIG. 4(c), sealing resin 11 made of a thermosetting resin is introduced through the opening of resin case 9, which is then subjected to a heat treatment, thereby thermal-hardening sealing resin 11, so that the opening of resin case 9 is sealed. In the manner as described above, semiconductor device 100 is manufactured.

Then, the functions and effects of the semiconductor device and the method of manufacturing a semiconductor device according to the present invention will be hereinafter described.

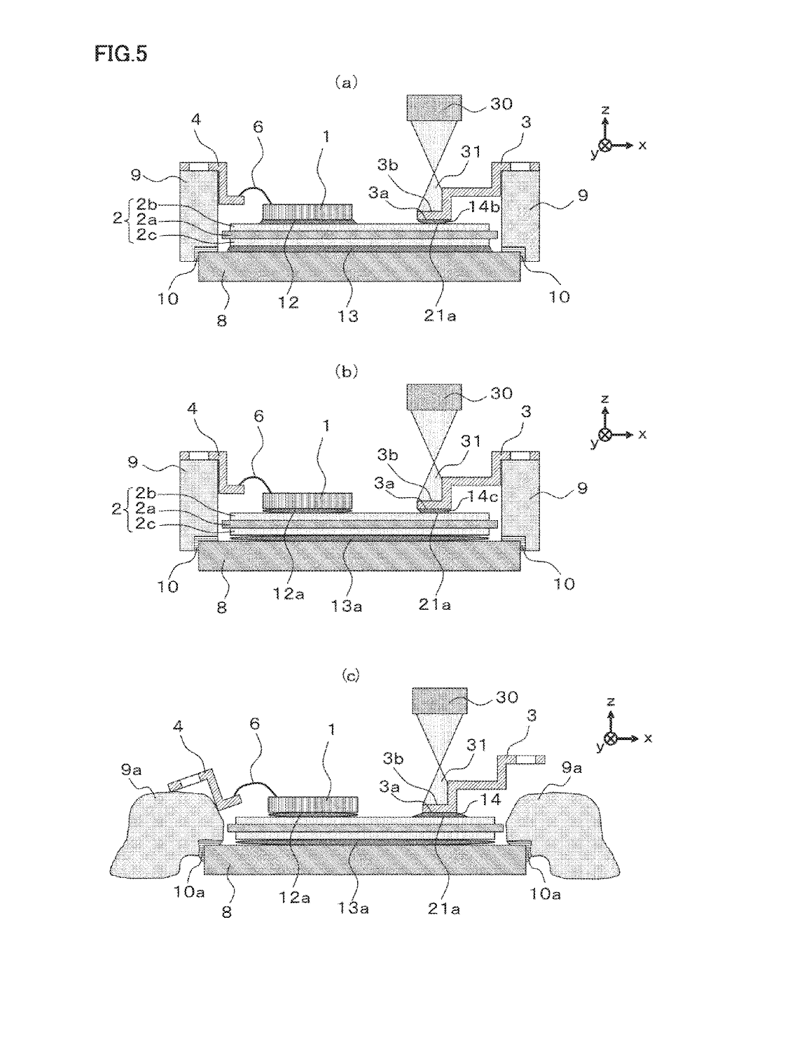

FIG. 5 is a cross-sectional view showing a method of manufacturing a semiconductor device shown as a comparative example. The method of manufacturing a semiconductor device shown in FIG. 5 is performed using a hard solder material having a melting temperature equal to or higher than 450° C. in place of a low-melting-point alloy, in accordance with the conventional method of manufacturing a semiconductor device disclosed in PTD 1.

In the method of manufacturing a semiconductor device disclosed in PTD 1, when laser beam 31 is applied to heating surface 3b of terminal electrode 3, the heat generated in heating surface 3b absorbing laser beam 31 is conducted due to heat conduction sequentially through second joining region 3a, the hard solder material, and first joining region 21a. Thus, laser beam 31 is applied to raise the temperature in second joining region 3a, the hard solder material, and first joining region 21a, which are described in descending order of temperature rise. Accordingly, as shown in FIG. 5(a), even when the temperature of hard solder material 14b reaches the melting temperature and then hard solder material 14b melts, the temperature of first joining region 21a does not reach the temperature enough to allow hard solder material 14b to wet first joining region 21a even though hard solder material 14b wets second joining region 3a. Consequently, hard solder material 14b does not wet first joining region 21a. Even when application of laser beam 31 is stopped in such a state to thereby solidify hard solder material 14b, conductor pattern 2b and terminal electrode 3 are not brazed. Thus, application of laser beam 31 needs to be continued to further raise the temperature of first joining region 21a.

As shown in FIG. 5(b), when application of laser beam 31 is continued, the temperature of first joining region 21a of conductor pattern 2b gradually rises, and hard solder material 14c starts to wet first joining region 21a. However, the temperature of first joining region 21a does not reach the temperature enough to allow hard solder material 14c to wet and spread over first joining region 21a. Thus, hard solder material 14c is to wet first joining region 21a at the contact angle greater than 90° between hard solder material 14c and first joining region 21a. Even when the temperature is not enough for hard solder material 14c to wet and spread over, but because the temperature of conductor pattern 2b is sufficiently raised, the temperatures of joining material 12 and joining material 13 are raised by heat conduction to their respective melting temperatures or higher. Thus, joining material 12 and joining material 13 melt. This results in: positional misalignment of insulating substrate 2 to heat dissipation plate 8; and positional misalignment of semiconductor element 1 to conductor pattern 2b, so that the reliability of the semiconductor device cannot be achieved. Also, even when application of laser beam 31 is stopped in this state to solidify hard solder material 14c, the sufficient reliability for the joining portion between conductor pattern 2b and terminal electrode 3 cannot be achieved since brazing is done with a fillet having a contact angle greater than 90° between first joining region 21a and hard solder material 14c.

As shown in FIG. 5(c), when application of laser beam 31 is further continued, the temperature of first joining region 21a of conductor pattern 2b is sufficiently raised, to allow hard solder material 14 to sufficiently wet first joining region 21a, thereby allowing excellent brazing at a contact angle less than 90°. However, since the temperature of heat dissipation plate 8 is raised too high due to heat conduction from conductor pattern 2b, resin case 9a and adhesive 10a may melt.

Namely, even when conductor pattern 2b and terminal electrode 3 are brazed using a hard solder material according to the conventional method of manufacturing a semiconductor device disclosed in PTD 1, the hard solder material cannot be caused to wet and spread over conductor pattern 2b and terminal electrode 3 for brazing since the hard solder material is higher in melting temperature than joining material 12, joining material 13, resin case 9, and adhesive 10.

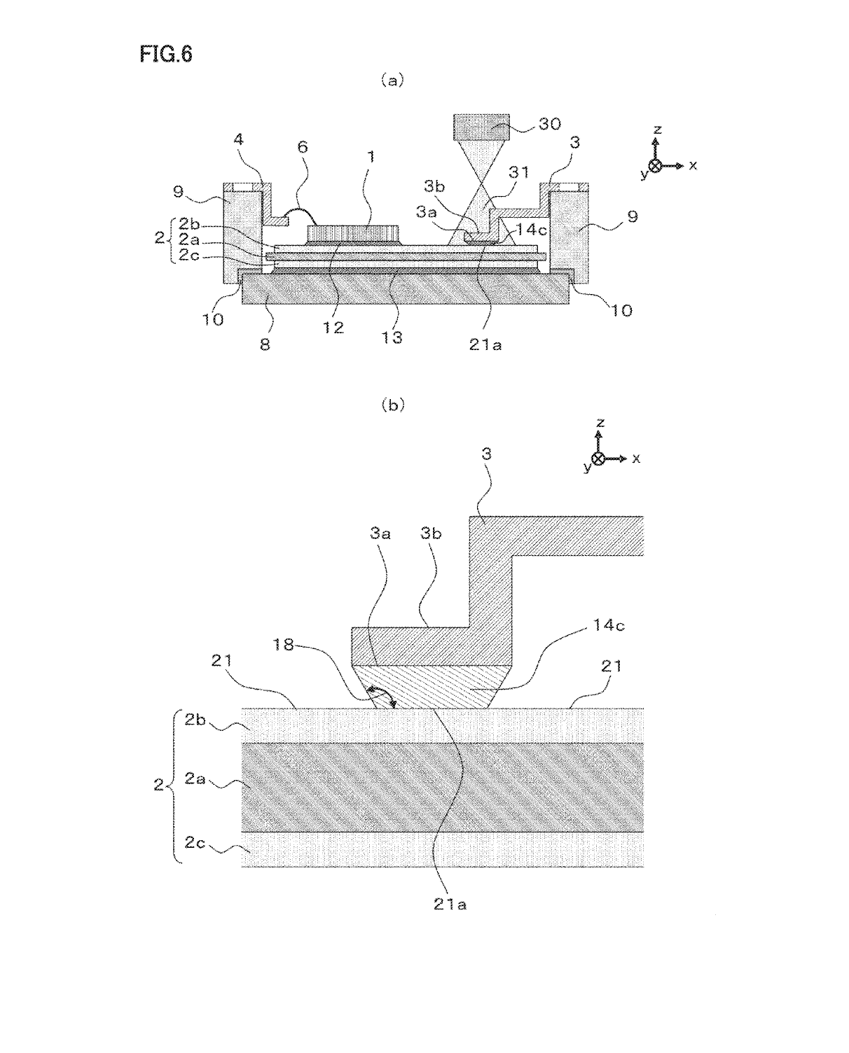

FIG. 6 is a cross-sectional view showing a method of manufacturing another semiconductor device in the first embodiment of the present invention. The method of manufacturing a semiconductor device shown in FIG. 6 is an improvement of the conventional method of manufacturing a semiconductor device shown in FIG. 5, in which the region to which laser beam 31 is applied is increased so as to apply laser beam 31 not only to heating surface 3b on the back side of second joining region 3a but also to the area around first joining region 21a. The method of manufacturing a semiconductor device shown in FIG. 6 is different from the method of manufacturing a semiconductor device shown in FIG. 4(a) of the present invention in the configuration in which roughened region 15 is not formed in first joining region 21a. FIG. 6(a) is a cross-sectional view showing the entire configuration of a method of manufacturing another semiconductor device. FIG. 6(b) is an enlarged view showing the joining portion between conductor pattern 2b and terminal electrode 3.

As shown in FIG. 6(a), when the region to which laser beam 31 is applied is increased more than that in FIG. 5 so as to apply laser beam 31 not only to heating surface 3b on the back side of second joining region 3a but also to the area around first joining region 21a, the portion of conductor pattern 2b to which laser beam 31 is applied absorbs laser beam 31 and then generates heat. Thus, the temperature of first joining region 21a can be raised without having to depend on heat conduction from heating surface 3b. Consequently, since the melted hard solder material wets first joining region 21a, first joining region 21a and second joining region 3a can be joined by hard solder material 14c. However, the heat of first joining region 21a is more likely to be diffused in the plane direction of insulating substrate 2 and in the direction of heat dissipation plate 8. Thus, it is difficult to raise the temperature of first joining region 21a higher than the temperature of second joining region 3a. Accordingly, in the case where laser beam 31 is applied not enough to allow melting of joining material 12 and joining material 13, a fillet having contact angle 18 greater than 90° may be formed as shown in FIG. 6(b). Thus, in order to more firmly join conductor pattern 2b and terminal electrode 3 by a hard solder material, it is more preferable that roughened region 15 is formed in first joining region 21a as shown in FIG. 4.

However, even by the method of manufacturing a semiconductor device shown in FIG. 6(a), when the thermal conductivity between first joining region 21a and the position at which semiconductor element 1 is joined is not sufficiently high because of a large distance between first joining region 21a on conductor pattern 2b and the position at which semiconductor element 1 is joined or because of a small cross-sectional area of conductor pattern 2b, the period of time of application of laser beam 31 is further increased, so that a fillet having contact angle 18 less than 90° can be formed. In such a case, conductor pattern 2b and terminal electrode 3 can be firmly joined by a hard solder material.

As described above, according to the method of manufacturing a semiconductor device of the present invention shown in FIG. 4, roughened region 15 is formed inside first joining region 21a of conductor pattern 2b, and laser beam 31 is applied to heating surface 3b on the back side of second joining region 3a in terminal electrode 3 and roughened region 15, thereby brazing the hard solder material. Thus, the absorptance of laser beam 31 applied to roughened region 15 is increased. Therefore, by applying laser beam 31 in an extremely short period of time, the temperature of first joining region 21a can be raised enough to allow the melted hard solder material to wet and spread over first joining region 21a without melting joining material 12 and joining material 13 that are formed by a soft solder material such as a solder material.

Furthermore, due to capillarity caused by the concavo-convex structure on roughened region 15, the melted hard solder material can be further more likely to wet and spread over roughened region 15. Consequently, as shown in FIG. 2, a fillet having contact angle 18 less than 90° is formed, so that conductor pattern 2b and terminal electrode 3 can be brazed by hard solder material 14. Then, the joining area between hard solder material 14 and conductor pattern 2b is larger than the joining area between hard solder material 14 and terminal electrode 3. Thus, even when a high current flows through power semiconductor element 1, the resistance in the joining portion can be reduced to thereby reduce loss.

The effect of causing the melted hard solder material to wet and spread over roughened region 15 by capillarity caused by the concavo-convex structure on roughened region 15 can be achieved not only by brazing through application of a laser beam but also by heating and melting the hard solder material by other methods. For example, when a hard solder material is brazed by a torch such as a gas burner or by electron beam irradiation, the effect of causing roughened region 15 to absorb more heating energy cannot be achieved, but the melted hard solder material can be caused to wet and spread over roughened region 15 by capillarity caused by the concavo-convex structure on roughened region 15. Thus, as shown in FIG. 2, a fillet having contact angle 18 less than 90° is formed, so that conductor pattern 2b and terminal electrode 3 can be brazed by hard solder material 14. Accordingly, the same effect as that achieved in the semiconductor device manufactured by brazing the hard solder material through application of a laser beam can be achieved.

Furthermore, in semiconductor device 100 of the present invention, conductor pattern 2b joined to ceramic plate 2a constituting insulating substrate 2 and terminal electrode 3 are joined by hard solder material 14, and contact angle 18 between conductor pattern 2b and hard solder material 14 is less than 90°. When conductor pattern 2b and terminal electrode 3 are formed of copper and hard solder material 14 is formed of copper phosphorus brazing filler metal, hard solder material 14 is greater in mechanical strength than conductor pattern 2b and terminal electrode 3. Accordingly, when thermal stress is applied to the joining portion between conductor pattern 2b and terminal electrode 3 due to heat generated during use of semiconductor device 100, conductor pattern 2b or terminal electrode 3 with smaller mechanical strength is more likely to undergo cracking.

Particularly when conductor pattern 2b and hard solder material 14 are joined at contact angle 18 greater than 90°, cracking occurs from the interface between conductor pattern 2b and hard solder material 14, thereby breaking insulating substrate 2. Thereby, the electrical insulation between semiconductor element 1 and heat dissipation plate 8 may become insufficient. It is preferable that conductor pattern 2b and hard solder material 14 are joined at contact angle 18 less than 90° also in order to suppress occurrence of such cracking leading to breakage of insulating substrate 2. Thus, as described in the present embodiment, it is particularly preferable that roughened region 15 is formed in first joining region 21a provided in conductor pattern 2b provided on an insulation substrate such as ceramic plate 2a.

Furthermore, it is suitable that the wavelength of the laser beam used in the method of manufacturing a semiconductor device of the present invention is equal to or greater than 500 nm and equal to or less than 1500 nm. Accordingly, it is recognized that roughened region 15 is greater in absorptance of light, which has a wavelength equal to or greater than 500 nm and equal to or less than 1500 nm, than the portion on main surface 21 of conductor pattern 2b where roughened region 15 is not formed. The method of increasing the absorptance of light having a wavelength equal to or greater than 500 nm and equal to or less than 1500 nm on the metal surface includes, in addition to roughening, a method of forming an oxide film on the surface of metal, and a method of forming another metal film with high absorptance of light having a wavelength equal to or greater than 500 nm and equal to or less than 1500 nm. By way of example, when an oxide film is formed on a smooth surface of copper, the emissivity with a wavelength of 1 μm can be increased from about 5% to about 85%. When a nickel film is formed on a smooth surface of copper, the emissivity with a wavelength of 1 μm can be increased from about 5% to about 30%. In other words, in place of roughened region 15, a light absorption region of an oxide film, a metal film and the like with high absorptance of light having a wavelength equal to or greater than 500 nm and equal to or less than 1500 nm may be formed.

In addition, the phenomenon of increasing the absorptance on the metal surface by roughening of the metal surface and formation of an oxide film on the metal surface occurs not only in the case of light having a wavelength equal to or greater than 500 nm and equal to or less than 1500 nm, but also in the case of light having a wavelength less than 500 nm and light having a wavelength greater than 1500 nm. Accordingly, at the present time, there is no practical usable laser apparatus that is suitable to the method of manufacturing a semiconductor device of the present invention, and also that is configured to output several kW or more with output light having a wavelength less than 500 nm or greater than 1500 nm. However, when a laser apparatus configured to output light having a wavelength less than 500 nm or greater than 1500 nm can output several kW or more, the laser apparatus with such wavelengths may be used to manufacture the semiconductor device of the present invention. Similarly, when a metal film is formed in place of a roughened region, in terms of the wavelength of the laser apparatus for manufacturing the semiconductor device of the present invention, this metal film may be formed of a material that is higher in absorptance of light having a wavelength of the laser apparatus than the material of conductor pattern 2b where first joining region 21a is provided.

When an oxide film or a metal film is formed in first joining region 21a, the process of forming an oxide film or a metal film may be performed in place of the process of forming roughened region 15 in first joining region 21a by sand blasting or etching as described with reference to FIG. 3(a). Specifically, an oxide film may be formed by an anodization treatment with masking through an opening provided in the portion of an oxide film, a metal film or the like where a light absorption region is formed, or a metal film may be formed by nickel plating, tin plating, or the like. The methods of forming an oxide film and a metal film are not limited thereto but may be any other methods.

In this way, also when, in place of roughened region 15, a light absorption region with high absorptance of light having a wavelength equal to or greater than 500 nm and equal to or less than 1500 nm or a light absorption region with high absorptance of light having a wavelength of the laser beam to be applied is formed inside first joining region 21a of conductor pattern 2b, the method of manufacturing a semiconductor device shown in FIG. 4 is employed to cause hard solder material 14 to wet and spread over the light absorption region of first joining region 21a, to form a fillet having contact angle 18 less than 90° between first joining region 21a and hard solder material 14, so that conductor pattern 2b and terminal electrode 3 can be brazed. Thus, it becomes possible to achieve a semiconductor device in which conductor pattern 2b and terminal electrode 3 are firmly joined by hard solder material 14. However, when a light absorption region formed of an oxide film or a metal film is formed in place of roughened region 15, the effect of causing the melted hard solder material to wet and spread by capillarity cannot be achieved. Accordingly, when brazing is performed not by application of a laser beam but by a hard solder material using a torch or an electron beam, it is preferable that roughened region 15 is formed inside first joining region 21a.

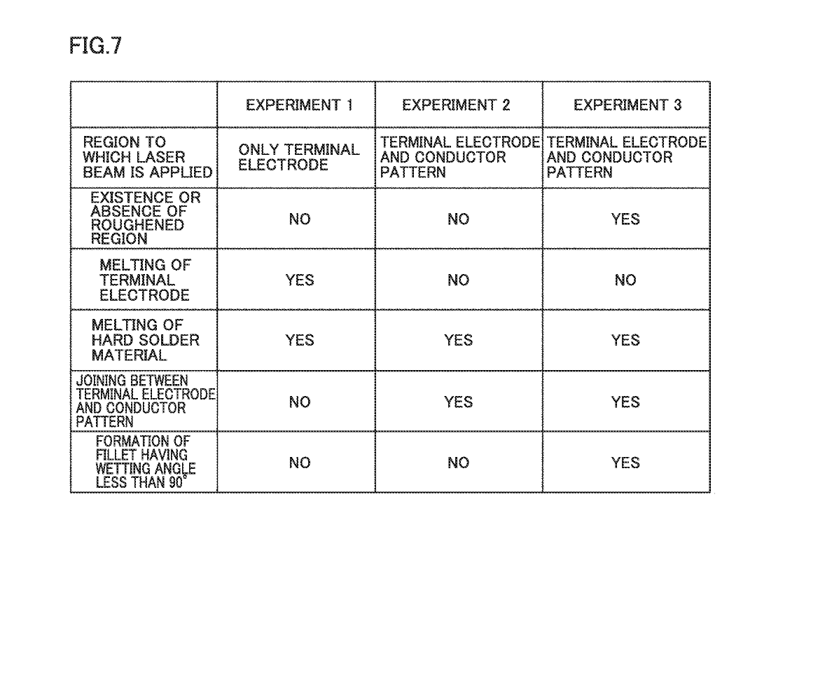

FIG. 7 is a diagram showing an experimental result obtained when the terminal electrode of the semiconductor device in the first embodiment of the present invention is joined by a hard solder material. In the experiment, the jointing state between terminal electrode 3 and conductor pattern 2b by hard solder material 14 was compared between: when laser beam 31 was applied only to terminal electrode 3 as in the conventional manufacturing method shown in FIG. 5; and when laser beam 31 was applied to terminal electrode 3 and conductor pattern 2b as in the manufacturing method of the present invention shown in FIG. 4. Furthermore, when laser beam 31 was applied to terminal electrode 3 and conductor pattern 2b, existence or absence of roughened region 15 in conductor pattern 2b was also compared.

Used in the experiment were: terminal electrode 3 having a length of 6 mm, a width of 4 mm and a thickness of 1 mm; an insulating substrate 2 made of an MN substrate in which a Cu conductor pattern 2b having a thickness of 0.3 mm was formed; and hard solder material 14 made of sheet-shaped copper phosphorus brazing filler metal having a length of 5 mm, a width of 4 mm and a thickness of 0.13 mm. Furthermore, insulating substrate 2 including conductor pattern 2b having roughened region 15 provided thereon was subjected to sand blasting such that roughened region 15 was formed of 0.5 mm of the outer circumference of second joining region 3a in terminal electrode 3. Then, the focusing position of laser beam 31 was adjusted so as to apply laser beam 31 to the region including only terminal electrode 3 or the region including terminal electrode 3 and roughened region 15 of conductor pattern 2b. In FIG. 7, Experiment 1 shows an experimental result obtained when laser beam 31 was applied to the region including only terminal electrode 3; Experiment 2 shows an experimental result obtained when laser beam 31 was applied to the region including terminal electrode 3 and conductor pattern 2b around the joining portion of terminal electrode 3; and Experiment 3 shows an experimental result obtained when laser beam 31 was applied to the region including terminal electrode 3 and roughened region 15 of conductor pattern 2b. Furthermore, a fiber laser with maximum output of 4 kW was used as a laser apparatus configured to output laser beam 31.

FIG. 7 shows an experimental result obtained by observing the jointing state between terminal electrode 3 and conductor pattern 2b on insulating substrate 2 after applying laser beam 31. As shown in FIG. 7, the experimental result was obtained by observing existence or absence of: melting of terminal electrode 3; melting of hard solder material 14; joining between terminal electrode 3 and conductor pattern 2b; and formation of a fillet having a wetting angle less than 90° with conductor pattern 2b. For achieving excellent joining between terminal electrode 3 and conductor pattern 2b, it is preferable that the terminal electrode does not melt, but preferable that the hard solder material melts, joining between the terminal electrode and the conductor pattern occurs, and a fillet having a wetting angle less than 90° is formed.

As shown in FIG. 7, in Experiment 1, terminal electrode 3 and hard solder material 14 melted, but melted hard solder material 14 did not wet and spread over conductor pattern 2b, and terminal electrode 3 and conductor pattern 2b were not joined. Also, since terminal electrode 3 and conductor pattern 2b were not joined, a fillet having a wetting angle less than 90° was also not formed.

In Experiment 2, terminal electrode 3 did not melt but hard solder material 14 melted, and terminal electrode 3 and conductor pattern 2b were joined. However, hard solder material 14 only slightly wet and spread over conductor pattern 2b, so that a fillet having a wetting angle less than 90° was not formed.

In Experiment 3, terminal electrode 3 did not melt, but hard solder material 14 melted, and terminal electrode 3 and conductor pattern 2b were joined. Then, since hard solder material 14 wet and spread over roughened region 15 of conductor pattern 2b, a fillet having a wetting angle less than 90° was formed. As shown in the experimental result in FIG. 7, it was confirmed that it is effective to provide roughened region 15 in the joining surface of conductor pattern 2b in order to cause hard solder material 14 to wet and spread over conductor pattern 2b.

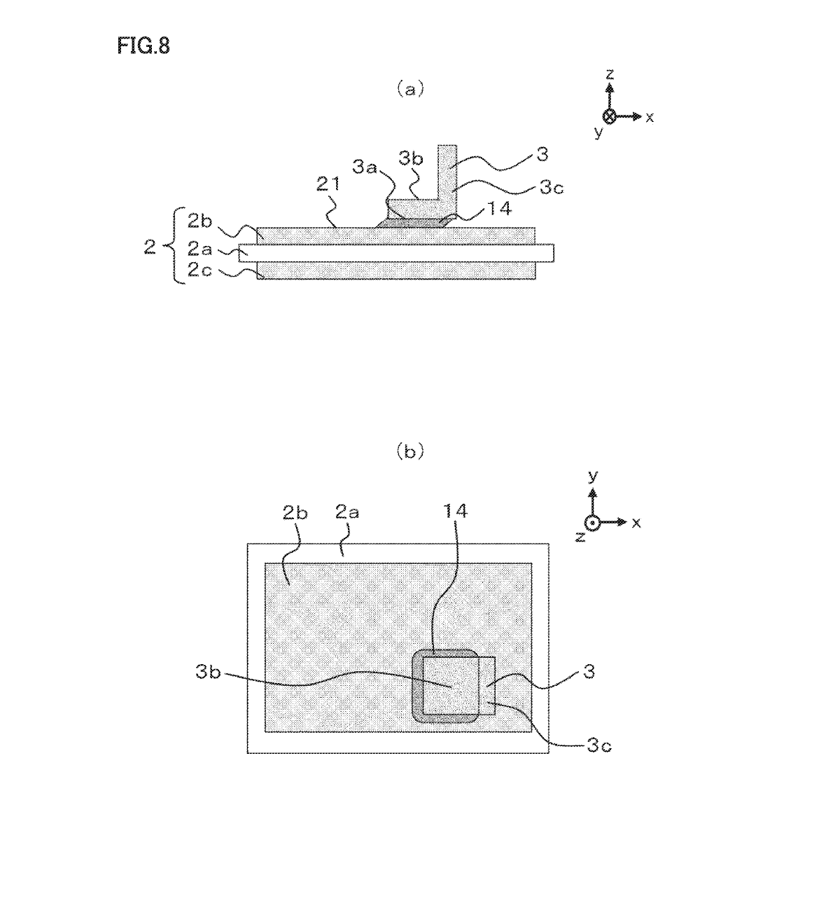

FIG. 8 is a partial cross-sectional view and a partial plan view showing another configuration of the semiconductor device in the first embodiment of the present invention. FIG. 8(a) is a partial cross-sectional view corresponding to FIG. 1(a), and FIG. 8(b) is a partial cross-sectional view corresponding to FIG. 1(b). FIG. 8 shows only the joining portion between insulating substrate 2 and terminal electrode 3 for clarifying the configuration, but the configurations other than the joining portion are the same as the configurations shown in FIG. 1 and therefore not shown.

As shown in FIG. 8(a), terminal electrode 3 joined to the main surface of conductor pattern 2b on insulating substrate 2 by hard solder material 14 is formed by bending a metal plate that forms terminal electrode 3. Specifically, terminal electrode 3 includes: a joining portion including second joining region 3a serving as a joining surface joined to conductor pattern 2b and heating surface 3b on the back side thereof; and an extension portion 3c connected to this joining portion and extending to resin case 9.

When hard solder material 14a is disposed on the main surface of conductor pattern 2b, and second joining region 3a of terminal electrode 3 is disposed on hard solder material 14a, to which laser beam 31 is applied from heating surface 3b of terminal electrode 3, laser beam 31 may be interrupted by extension portion 3c of terminal electrode 3. In this case, laser beam 31 is not applied to conductor pattern 2b on the side where extension portion 3c of terminal electrode 3 is provided and around second joining region 3a of terminal electrode 3 on the main surface of conductor pattern 2b. Accordingly, the temperature of this portion can be set to be less than the melting point of hard solder material 14. Consequently, hard solder material 14 is suppressed from wetting and spreading over extension portion 3c of conductor pattern 2b, but hard solder material 14 is allowed to wet and spread over the joining portion of terminal electrode 3 heated to the temperature equal to or higher than the melting point of hard solder material 14. Thereby, a fillet having an acute contact angle between hard solder material 14 and second joining region 3a of terminal electrode 3 can be formed on the extension portion 3c side of second joining region 3a of terminal electrode 3, as shown in FIG. 8.

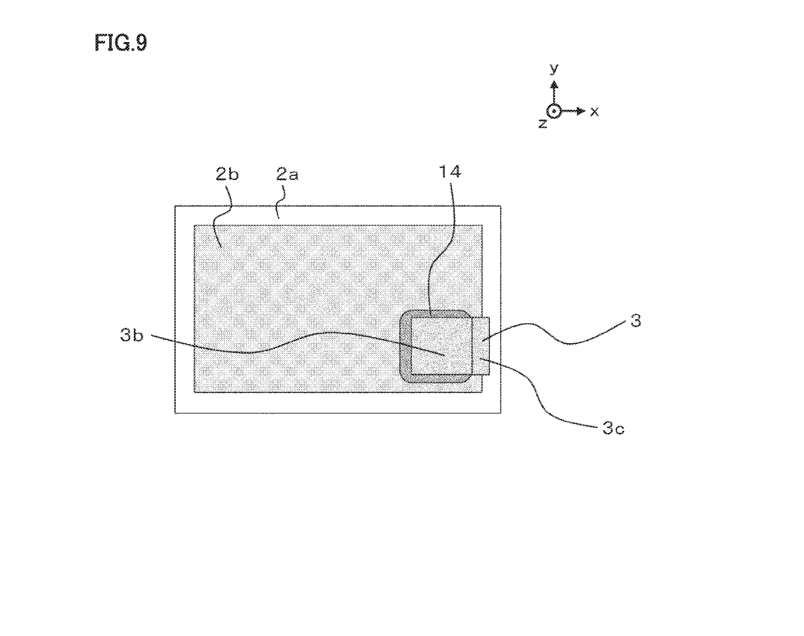

FIG. 9 is a partial plan view showing another configuration of the semiconductor device in the first embodiment of the present invention. FIG. 9 is a partial cross-sectional view corresponding to FIG. 8(b), and the cross-sectional view of the joining portion between terminal electrode 3 and conductor pattern 2b shown in FIG. 9 is the same as that of FIG. 8(a). Specifically, hard solder material 14 in second joining region 3a as a joining surface of terminal electrode 3 is formed such that the contact angle between hard solder material 14 and second joining region 3a of terminal electrode 3 is an acute angle on the extension portion 3c side of terminal electrode 3. The joining portion in FIG. 9 is different from the joining portion in FIG. 8(b) in that the end of the joining portion on the extension portion 3c side is located closer to the end of conductor pattern 2b.

As shown in FIG. 8(a), the contact angle between hard solder material 14 and second joining region 3a of terminal electrode 3 on the extension portion 3c side is an acute angle. Thus, even when terminal electrode 3 is joined in the vicinity of the end of conductor pattern 2b on the right side of the figure on the plane of the sheet of paper as shown in FIG. 9, the end of the joining portion between hard solder material 14 and conductor pattern 2b on the right side of the figure on the plane of the sheet of paper is located on the inner side of conductor pattern 2b than the end of the joining portion between hard solder material 14 and terminal electrode 3 on the right side of the figure on the plane of the sheet of paper, so that breakage of ceramic plate 2a upon joining of terminal electrode 3 can be suppressed.

In contrast to FIG. 8(a), in the case where the contact angle between hard solder material 14 and second joining region 3a of terminal electrode 3 on the extension portion 3c side is an obtuse angle like the contact angle between hard solder material 14 and second joining region 3a of terminal electrode 3 on the opposite side of extension portion 3c, ceramic plate 2a may be broken when terminal electrode 3 is joined in the vicinity of the end of conductor pattern 2b. Specifically, when laser beam 31 is applied to the end of conductor pattern 2b to heat the end of conductor pattern 2b during joining of terminal electrode 3, melted hard solder material 14 wets and spreads over the end of conductor pattern 2b, so that conductor pattern 2b is pulled due to the difference in coefficient of linear expansion between insulating substrate 2 and hard solder material 14, thereby breaking ceramic plate 2a from the end of conductor pattern 2b.

However, in the semiconductor device of the present invention shown in FIG. 9, the contact angle between hard solder material 14 and second joining region 3a of terminal electrode 3 on the extension portion 3c side is set at an acute angle, thereby allowing suppression of breakage of ceramic plate 2a resulting from the difference in coefficient of linear expansion between insulating substrate 2 and hard solder material 14. Thus, terminal electrode 3 can be disposed closer to the end of conductor pattern 2b than in the conventional case where solder is used. Accordingly, the size of conductor pattern 2b required for joining of terminal electrode 3 can be reduced, so that the semiconductor device can be entirely further reduced in size.

Then, the semiconductor device in which a roughened region having another configuration is formed inside the first joining region will be hereinafter described.

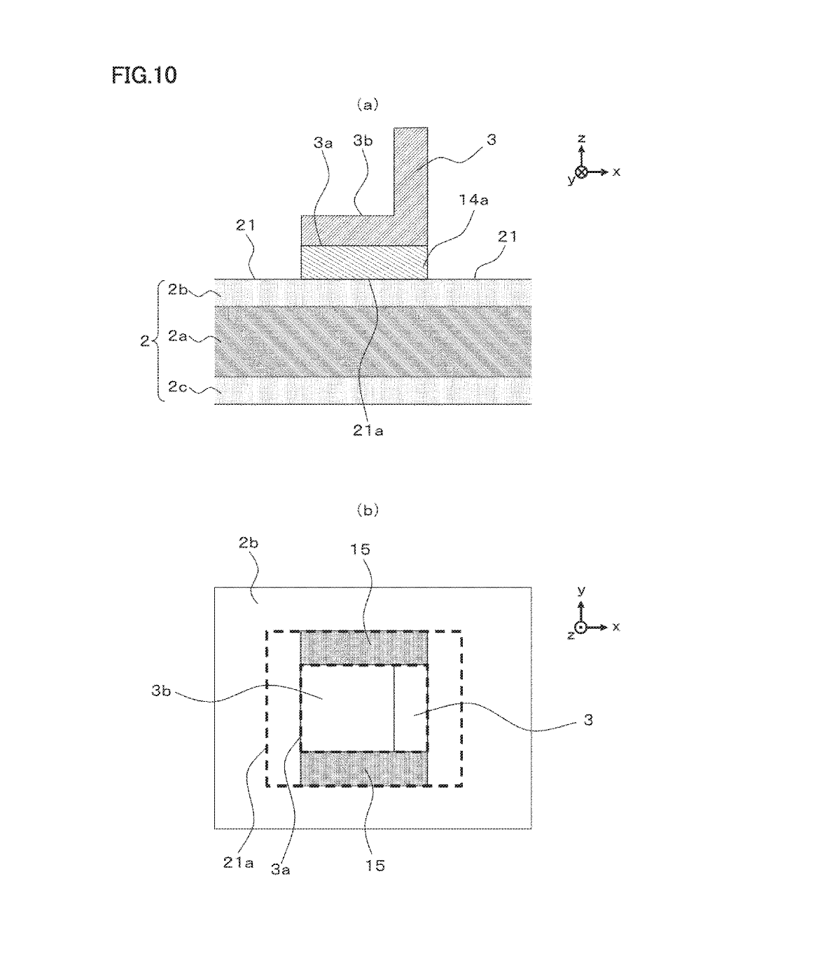

FIG. 10 is a partial enlarged view showing a partial configuration of the semiconductor device having another configuration in the first embodiment of the present invention. FIG. 10 is also an enlarged view showing the state where sheet-shaped hard solder material 14a is disposed between first joining region 21a and second joining region 3a as shown in FIG. 3 (c), that is, the state before first joining region 21a and second joining region 3a are brazed. The reason why an enlarged view before brazing is shown is as follows. Specifically, after brazing, the hard solder material wets and spreads over first joining region 21a, so that hard solder material 14 covers roughened region 15. Thus, an enlarged view of roughened region 15 after brazing becomes complicated. FIG. 10(a) is a cross-sectional view showing the joining portion between first joining region 21a and second joining region 3a. FIG. 10(b) is a plan view showing the joining portion between first joining region 21a and second joining region 3a. FIG. 10(b) also shows the peripheral edge of first joining region 21a and the peripheral edge of second joining region 3a by dashed lines.

In the semiconductor device shown in FIGS. 1 and 2, the roughened region provided inside the first joining region is provided along the entire peripheral edge of the second joining region in a plan view. In the semiconductor device shown in FIG. 10, however, roughened region 15 is provided along a part of the peripheral edge of the second joining region in a plan view. Roughened region 15 is provided in a portion along each of sides in parallel with the X-axis among four sides of the peripheral edge of second joining region 3a, but is not provided in a portion along each of sides in parallel with the Y axis among these four sides. This is because the side on the right side on the plane of the sheet of paper showing FIG. 10 among the sides extending in parallel with the Y-axis and forming the peripheral edge of second joining region 3a is prevented from being irradiated with a laser beam by terminal electrode 3 bent from second joining region 3a in the Z-axis direction. In this way, in consideration of the range in which a laser beam is applied, roughened region 15 can be provided inside first joining region 21a and at an optional position on the outside of the peripheral edge of second joining region 3a in a plan view.

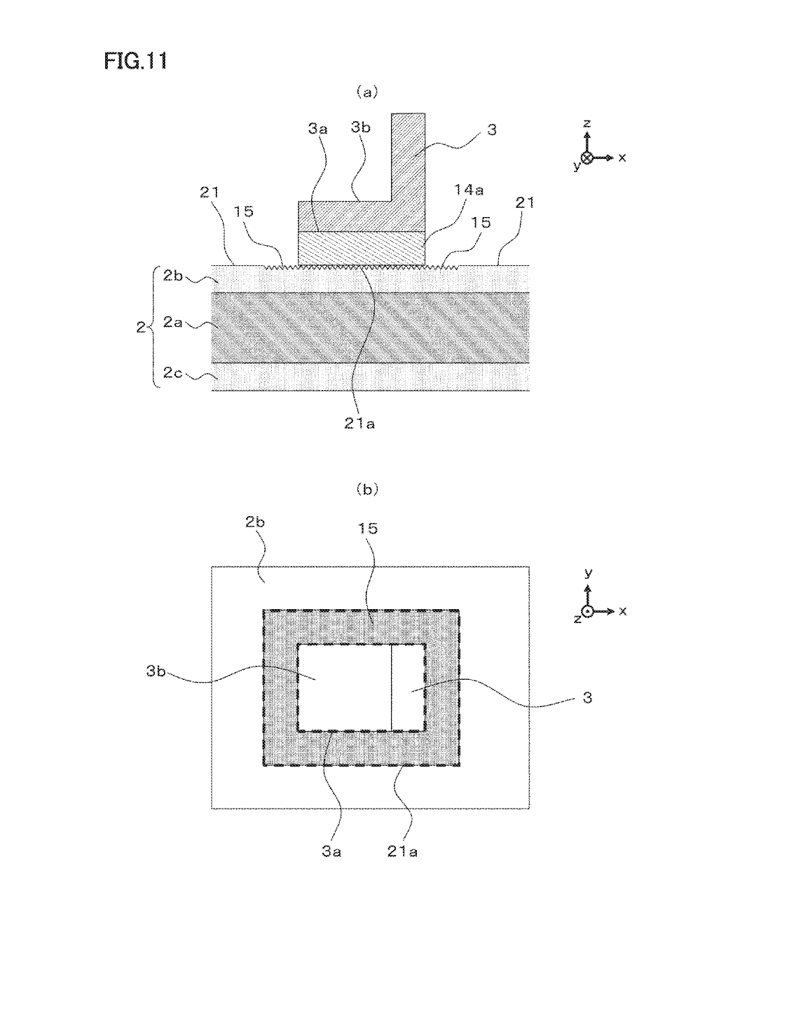

FIG. 11 is a partial enlarged view showing a partial configuration of the semiconductor device having another configuration in the first embodiment of the present invention. As in FIG. 10, FIG. 11 is also an enlarged view showing the state before first joining region 21a and second joining region 3a are brazed. FIG. 11(a) is a cross-sectional view showing the joining portion between first joining region 21a and second joining region 3a. FIG. 11(b) is a plan view showing the joining portion between first joining region 21a and second joining region 3a. As in FIG. 10(b), FIG. 11(b) shows the peripheral edge of first joining region 21a and the peripheral edge of second joining region 3a by dashed lines.

In the semiconductor device shown in FIG. 11, roughened region 15 is provided not only on the outside of the peripheral edge of second joining region 3a in a plan view in the Z-axis direction on the inside of first joining region 21a, but also on the inside of the peripheral edge of second joining region 3a. In other words, roughened region 15 is provided also in the portion facing second joining region 3a. It is preferable that roughened region 15 is provided also in the portion located inside first joining region 21a and facing second joining region 3a in this way because the wettability and the spreadability onto first joining region 21a of conductor pattern 2b can be further improved when the hard solder material melts.

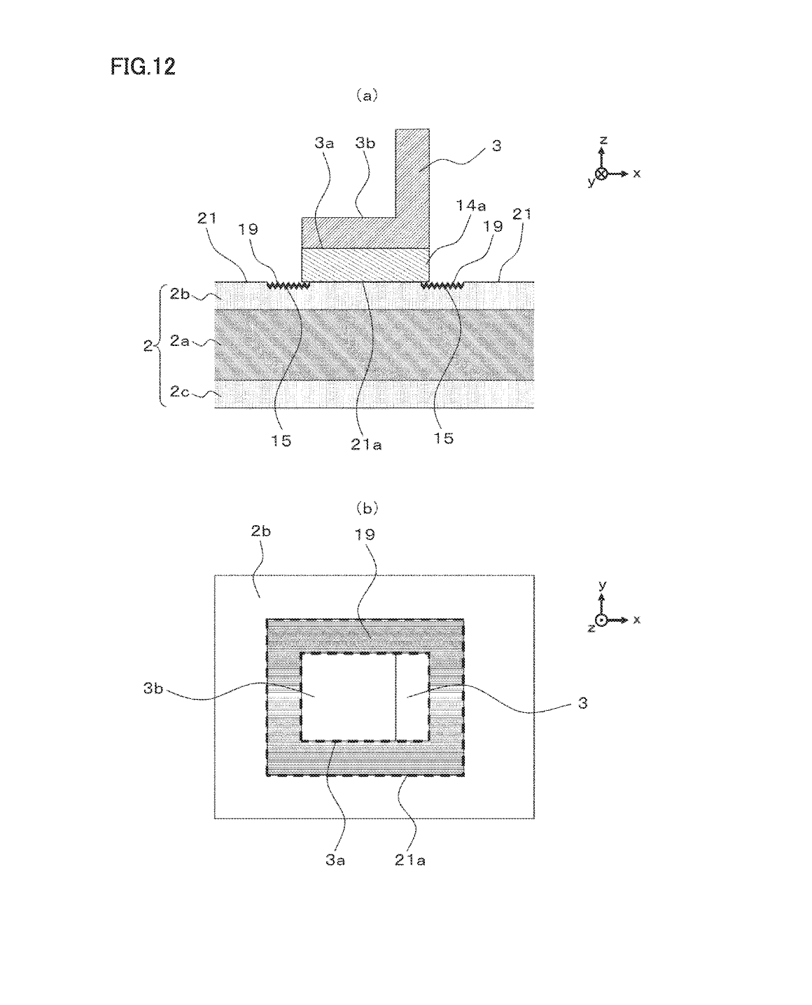

FIG. 12 is a partial enlarged view showing a partial configuration of the semiconductor device having another configuration in the first embodiment of the present invention. As in FIG. 10, FIG. 12 is also an enlarged view showing the state before first joining region 21a and second joining region 3a are brazed. FIG. 12(a) is a cross-sectional view showing the joining portion between first joining region 21a and second joining region 3a. FIG. 12(b) is a plan view showing the joining portion between first joining region 21a and second joining region 3a. As in FIG. 10(b), FIG. 12(b) shows the peripheral edge of first joining region 21a and the peripheral edge of second joining region 3a by dashed lines.

In the semiconductor device shown in FIG. 12, a light absorption film 19 is provided on roughened region 15. Light absorption film 19 is an oxide film made of a metal material that forms conductor pattern 2b, for example. Alternatively, light absorption film 19 is a metal film formed of a metal material that is higher in absorptance of light having a wavelength equal to or greater than 500 nm and equal to or less than 1500 nm or light having a wavelength of the laser beam to be applied than the metal material forming conductor pattern 2b.

Such light absorption film 19 can be formed by the following method, for example, when conductor pattern 2b is formed of copper. First, on the surface of conductor pattern 2b, a photoresist is formed, which is opened in the portion where roughened region 15 is to be formed, which is then subjected to a roughening treatment by sand blasting or the like. Then, an anodization treatment is performed using a copper sulfate aqueous solution while keeping the photoresist, to thereby remove the photoresist. Thereby, a black oxide film as light absorption film 19 is formed on the surface of roughened region 15. On the other hand, after a photoresist is formed and a roughening treatment is performed, nickel plating or tin plating is performed to remove the photoresist, thereby forming a nickel or tin metal film as light absorption film 19 on the surface of roughened region 15. Nickel and tin are higher in absorptance of light, which has a wavelength equal to or greater than 500 nm and equal to or less than 1500 nm, than copper. Thus, nickel and tin are suitable for a metal film used as light absorption film 19.

In addition, when a metal film is formed as light absorption film 19, the melting temperature of the metal material forming the metal film may be lower than the melting temperature of the hard solder material. The metal film serving as light absorption film 19 only has to increase the absorptance of the laser beam to be applied during brazing. Accordingly, it is not problematic if such the metal film is mixed with the melted hard solder material after it absorbs the laser beam to thereby raise the temperature of roughened region 15. Also, in order to improve the wettability between second joining region 3a and the hard solder material, a metal film similar to the metal film formed on roughened region 15 of first joining region 21a as light absorption film 19 may be formed on the surface of second joining region 3a.

The present first embodiment has been described as a suitable example with regard to the case where conductor pattern 2b having first joining region 21a and terminal electrodes 3 having second joining region 3a each are made of copper, and the case where hard solder material 14 is made of copper phosphorus brazing filler metal, but the present invention is not limited thereto. A laser beam is applied for an extremely short period of time during brazing. In this case, however, since the laser beam is applied for such a short period of time, the temperature control of the portion to which a laser beam is applied may become difficult. It is preferable to use the hard solder material having a melting temperature that is lower, by 250° C. or higher, than the melting temperatures of conductor pattern 2b and terminal electrode 3 since the hard solder material can be melted without melting conductor pattern 2b and terminal electrode 3 even when the laser beam is applied for a short period of time.

Furthermore, it is preferable that conductor pattern 2b and terminal electrode 3 are made of the same metal material, but may be formed of different metal materials. When conductor pattern 2b and terminal electrode 3 are formed of different materials, it is preferable that conductor pattern 2b provided on insulating substrate 2 is higher in melting temperature than terminal electrode 3 in order to suppress breakage of insulating substrate 2 by thermal stress.

The present first embodiment has been described with regard to the case where a SiC MOSFET is used for power semiconductor element 1. The SiC MOSFET can be operated at a higher temperature environment than that of a semiconductor element formed of silicon (Si). Thus, semiconductor device 100 including semiconductor element 1 formed using a SiC MOSFET is used in a higher temperature environment in many cases. In such a high temperature environment, a large thermal stress and a large tensile stress occur in the joining portion between conductor pattern 2b provided on insulating substrate 2 and terminal electrode 3. Further, the material strength is also significantly decreased due to such a high temperature environment. Accordingly, the present invention is suitable for semiconductor device 100 including semiconductor element 1 formed using a SiC MOSFET.

According to semiconductor device 100 in the first embodiment of the present invention as described above, a roughened region is provided on the inside of the first joining region provided in the conductor pattern on the insulating substrate and on the outside of the peripheral edge of the second joining region provided in the terminal electrode that is joined to the first joining region in a plan view. Thus, when a laser beam is applied to the hard solder material provided between the first joining region and the second joining region, the absorptance of the laser beam is raised by the roughened region, so that the temperature rise in the first joining region can be increased. Consequently, the hard solder material wets and spreads over the roughened region provided in the first joining region, with the result that it becomes possible to achieve a semiconductor device in which the conductor pattern and the terminal electrode are firmly joined by the hard solder material. Furthermore, since the melted hard solder material is caused to wet and spread over the roughened region by capillarity, it becomes possible to achieve a semiconductor device in which the conductor pattern and the terminal electrode are firmly joined by the hard solder material.

### Second Embodiment

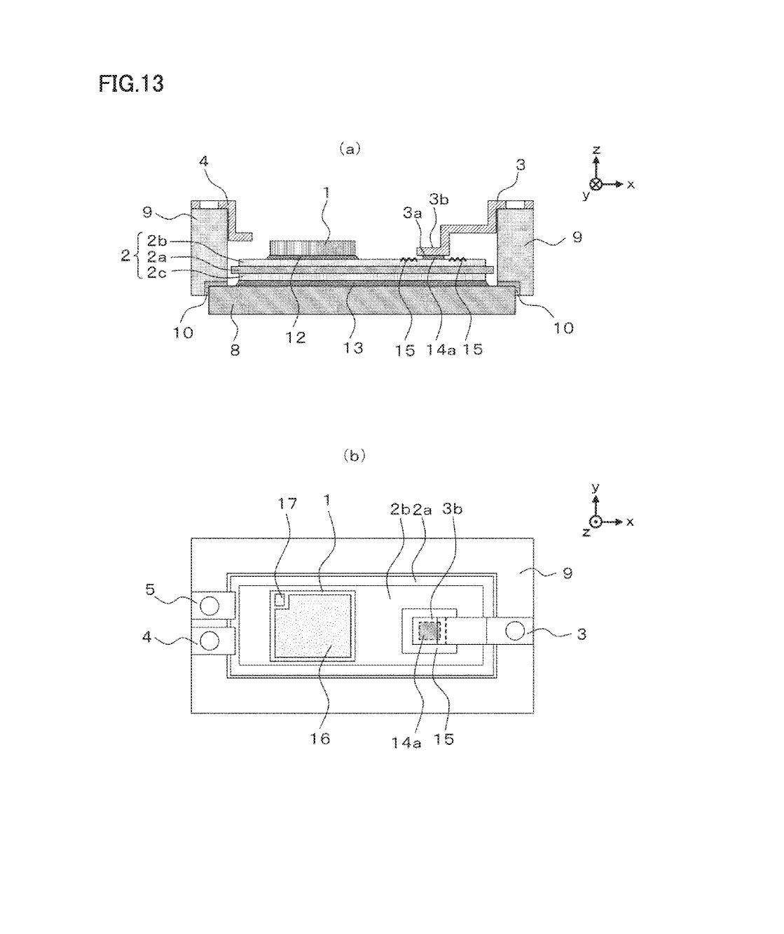

FIG. 13 is a cross-sectional view and a plan view showing a method of manufacturing a semiconductor device in the second embodiment of the present invention. FIG. 13(a) corresponds to FIG. 3(c) in the first embodiment, and is a cross-sectional view showing the state where sheet-shaped hard solder material 14a is disposed on the main surface of conductor pattern 2b provided on insulating substrate 2, and terminal electrode 3 is disposed on hard solder material 14a. Furthermore, FIG. 13(b) is a plan view corresponding to FIG. 13(a). FIG. 13(b) shows sheet-shaped hard solder material 14a with hatching. The method of manufacturing a semiconductor device described in the present second embodiment is different from the first embodiment in that sheet-shaped hard solder material 14a is disposed so as to be entirely covered with terminal electrode 3, to which a laser beam is applied. In the present second embodiment, the features different from those in the first embodiment will be described but the same features as those in the first embodiment will not be described.

As shown in FIGS. 3(a) and 3(b), sheet-shaped hard solder material 14a disposed on the main surface of conductor pattern 2b is entirely covered with terminal electrode 3 in a plan view seen in the Z direction. In other words, terminal electrode 3 is disposed to entirely cover sheet-shaped hard solder material 14a in a plan view. Terminal electrode 3 has, in the joining region joined to the main surface of conductor pattern 2b, second joining region 3a formed almost in parallel with the main surface of conductor pattern 2b while sheet-shaped hard solder material 14a disposed on conductor pattern 2b is provided so as to be located inside second joining region 3a in a plan view. In other words, the length of sheet-shaped hard solder material 14a in the x direction is shorter than the length of second joining region 3a of terminal electrode 3 in the x direction, and the width of sheet-shaped hard solder material 14a in the y direction is shorter than the width of second joining region 3a of terminal electrode 3 in the y direction. When seen in the Z direction in which laser beam 31 is applied, hard solder material 14a is covered with terminal electrode 3. Accordingly, even when laser beam 31 is applied, laser beam 31 is not directly applied to hard solder material 14a.

In the method of manufacturing a semiconductor device in the present second embodiment shown in FIG. 13, when laser beam 31 is applied to heating surface 3b of terminal electrode 3 and roughened region 15 provided on the main surface of conductor pattern 2b as shown in FIG. 4, laser beam 31 is not interrupted by hard solder material 14a that protrudes from the outer periphery of the terminal electrode to the outside, so that laser beam 31 can be reliably applied to roughened region 15. Consequently, the temperatures of terminal electrode 3 and conductor pattern 2b can be raised in the state where the difference in temperature between terminal electrode 3 and conductor pattern 2b is kept small, so that melted hard solder material 14 can be caused to more reliably wet and spread over roughened region 15 on conductor pattern 2b. Consequently, the reliability of joining between terminal electrode 3 and conductor pattern 2b can be further improved.

In order to cause hard solder material 14 to equally wet and spread over second joining region 3a of terminal electrode 3 after melting of hard solder material 14, it is preferable that the aspect ratio between the width and the length of sheet-shaped hard solder material 14a disposed on the main surface of conductor pattern 2b in FIG. 13 is the same as the aspect ratio between the width and the length of second joining region 3a of terminal electrode 3. Furthermore, it is preferable that the center of sheet-shaped hard solder material 14a coincides with the center of second joining region 3a of terminal electrode 3. By such a configuration, terminal electrode 3 and conductor pattern 2b can be more equally heated by application of laser beam 31. Consequently, since the difference in temperature between terminal electrode 3 and conductor pattern 2b can be reduced, it is preferable that the reliability of joining between terminal electrode 3 and conductor pattern 2b can be further more improved.

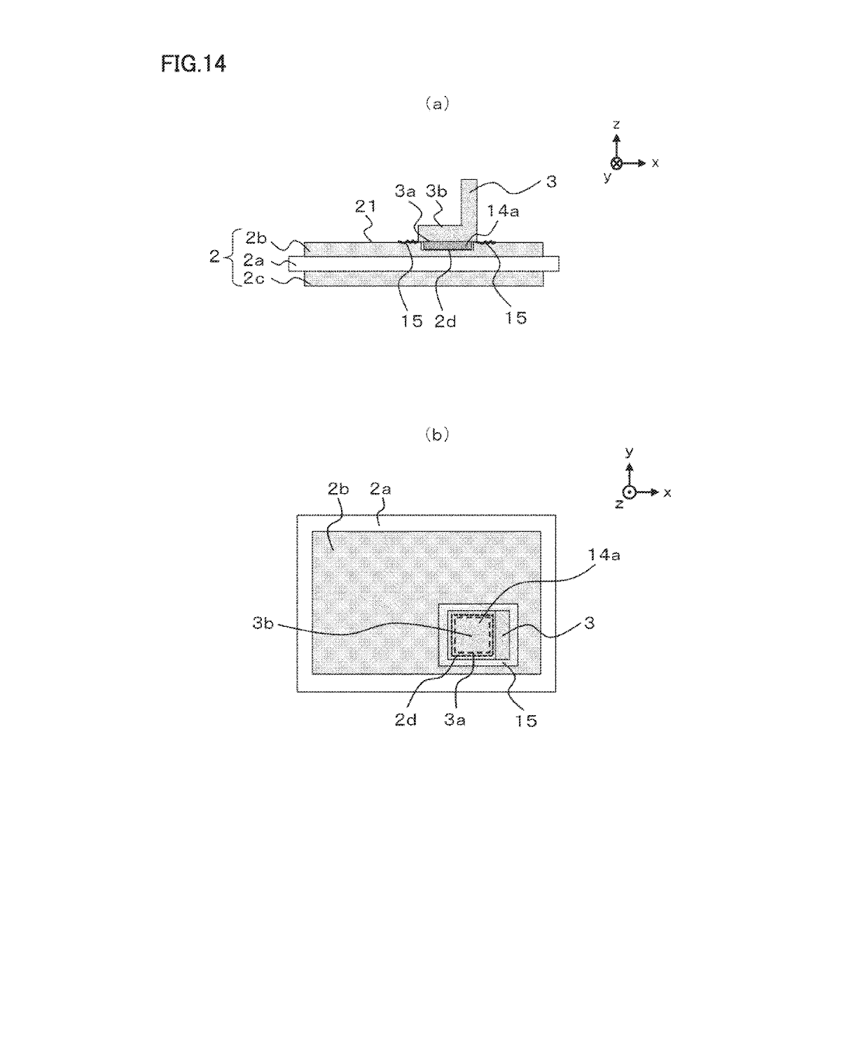

FIGS. 14 to 17 each are a partial cross-sectional view and a partial plan view showing a method of manufacturing a semiconductor device having another configuration in the second embodiment of the present invention. FIGS. 14 to 17 each show the state where sheet-shaped hard solder material 14a is disposed on the main surface of conductor pattern 2b provided on insulating substrate 2, and terminal electrode 3 is disposed on hard solder material 14a, as in FIG. 13. For the sake of easy understanding, FIGS. 14 to 17 each show only the configuration of the joining portion between terminal electrode 3 and conductor pattern 2b but do not show other configurations of a semiconductor element and the like. Other configurations of a semiconductor element and the like are the same as those in FIG. 13. Also, each of FIGS. 14(a), 15(a), 16(a), and 17(a) corresponds to FIG. 13(a), and each of FIGS. 14(b), 15(b), 16(b), and 17(b) corresponds to FIG. 13(b). In the following, the features different from those in FIGS. 13(a) and 13(b) will be described, but the same features will not be described.

The semiconductor device shown in FIG. 14 is provided with a concave portion 2d on the main surface side of conductor pattern 2b on insulating substrate 2 such that concave portion 2d is smaller in size than second joining region 3a serving as a joining surface of terminal electrode 3. It is preferable that the depth of concave portion 2d is less than the thickness of conductor pattern 2b, and that concave portion 2d has a bottom surface on the inside of conductor pattern 2b. When sheet-shaped hard solder material 14a is disposed on the main surface of conductor pattern 2b, hard solder material 14a is disposed inside concave portion 2d as shown in FIG. 14(a). Thereby, the position of hard solder material 14a can be prevented from being displaced when terminal electrode 3 is disposed. Consequently, it becomes less likely that laser beam 31 is interrupted by the hard solder material displaced in position, to prevent laser beam 31 from being applied to roughened region 15 of conductor pattern 2b, as described above. Accordingly, it is preferable that the reliability of joining between terminal electrode 3 and conductor pattern 2b can be still further improved.

In FIG. 14, concave portion 2d for positioning hard solder material 14a is provided in conductor pattern 2b, but a similar concave portion may be provided in second joining region 3a serving as a joining surface of terminal electrode 3.

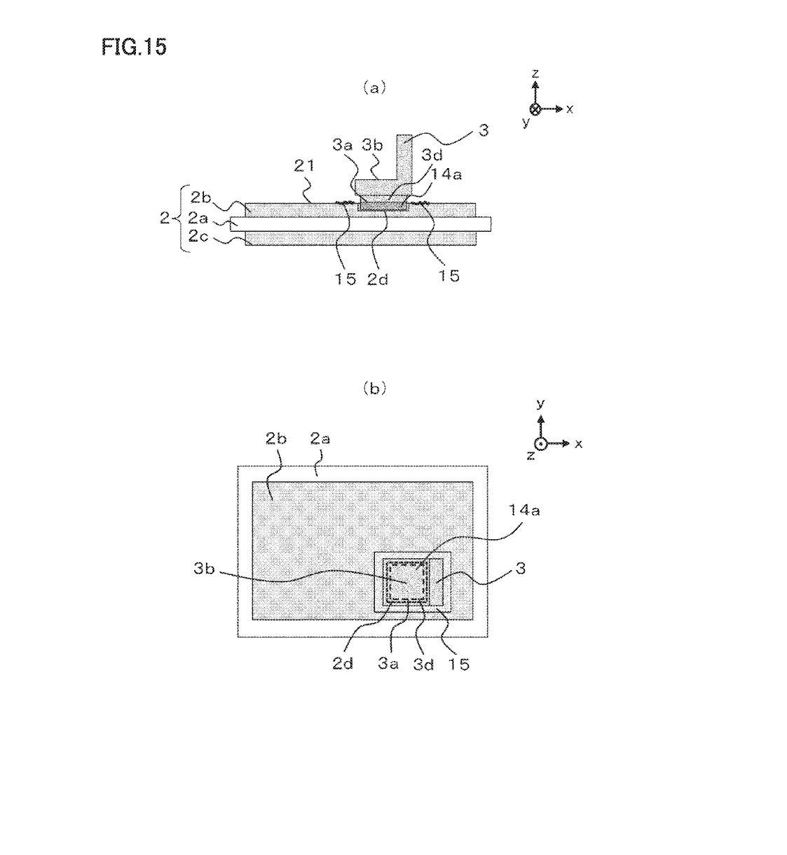

In addition to the configuration of the semiconductor device shown in FIG. 14, the semiconductor device shown in FIG. 15 is provided with a convex portion 3d in second joining region 3a serving as a joining surface of terminal electrode 3. Convex portion 3d of terminal electrode 3 is inserted into concave portion 2d of conductor pattern 2b. The above-described configuration is preferable since the positional misalignment of terminal electrode 3 can be prevented while terminal electrode 3 and the main surface of conductor pattern 2b can be more firmly joined even though joined hard solder material 14 is reduced in thickness.

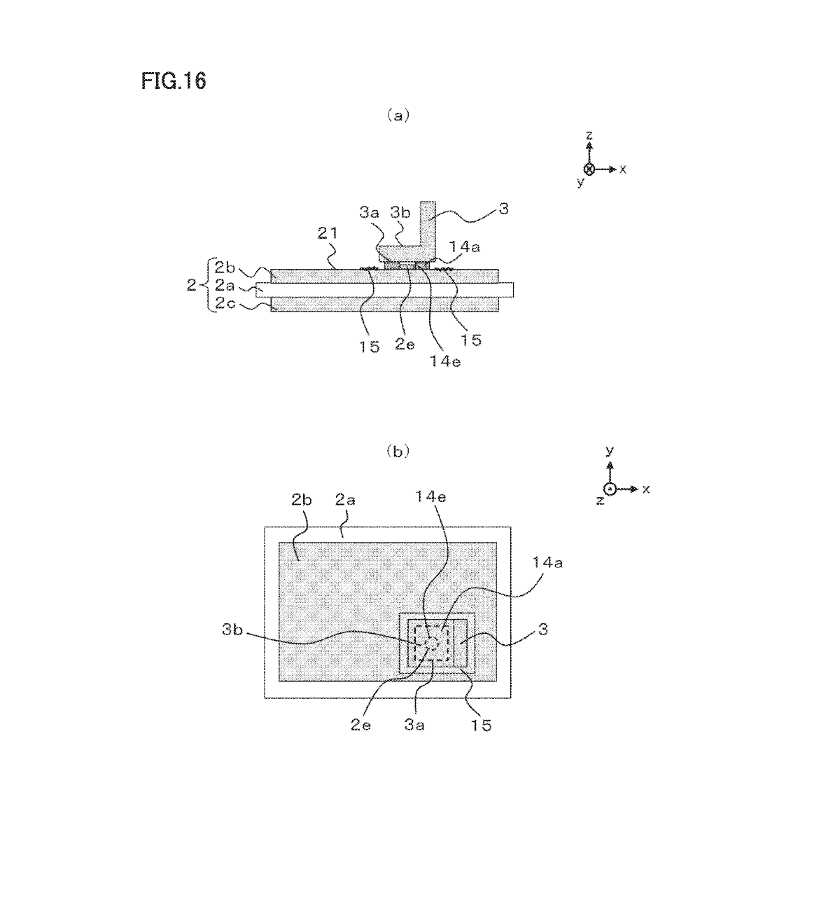

In the semiconductor device shown in FIG. 16, a convex portion 2e is provided in the joining region located on the main surface of conductor pattern 2b and to be joined to terminal electrode 3. Also, a concave portion 14e is provided in sheet-shaped hard solder material 14a disposed on the main surface of conductor pattern 2b. Hard solder material 14a is disposed on the main surface of conductor pattern 2b in the state where convex portion 2e is inserted into concave portion 14e. Concave portion 14e provided in hard solder material 14a may be shaped to have a bottom surface, or may be shaped to have a through hole penetrating through hard solder material 14a in the thickness direction. By such a configuration, the positional misalignment between hard solder material 14a and terminal electrode 3 can be prevented, so that the reliability of joining between terminal electrode 3 and conductor pattern 2b can be further more improved.

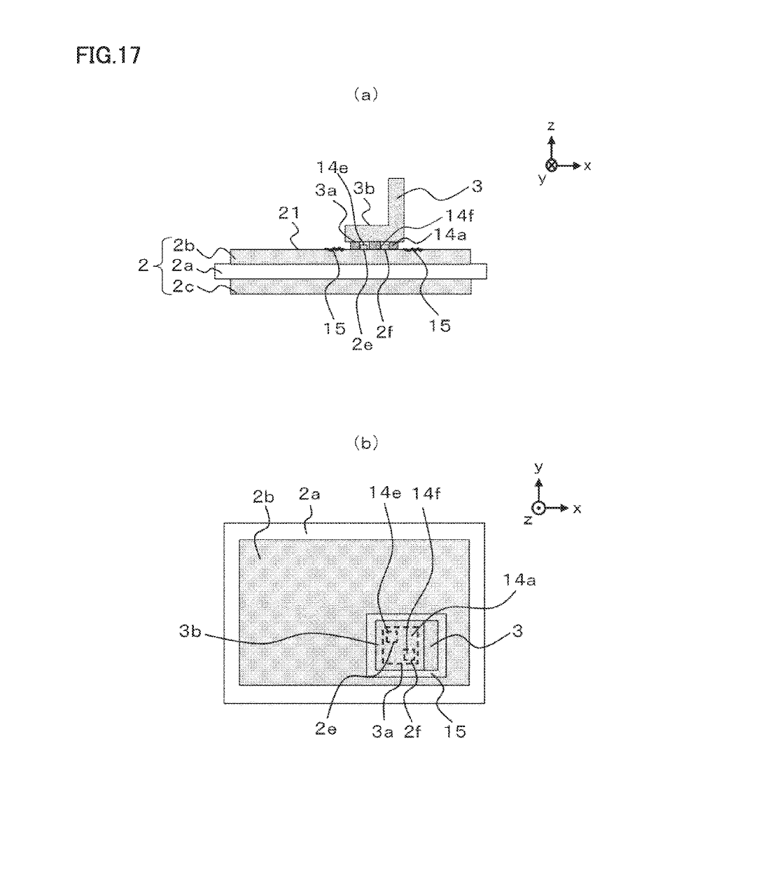

In the semiconductor device shown in FIG. 17, a convex portion 2e and a convex portion 2f are provided in the joining region located on the main surface of conductor pattern 2b and to be joined to terminal electrode 3. Concave portion 14e and concave portion 14f are provided so as to correspond to the opposite angle of sheet-shaped hard solder material 14a disposed on the main surface of conductor pattern 2b. Concave portion 14e and concave portion 14f may be shape to have a bottom surface or may be shaped to have a through hole. Terminal electrode 3 is disposed on hard solder material 14a in the state where convex portion 2e is inserted into concave portion 14e and convex portion 2f is inserted into concave portion 14f By such a configuration, not only the positional misalignment of hard solder material 14a but also rotational misalignment can be prevented. The number, the shape and the position of each of the convex portions provided in conductor pattern 2b and the concave portions provided in hard solder material 14 are not limited as long as positional misalignment and rotational misalignment can be prevented.

In addition, the convex portion may be provided in terminal electrode 3 not in conductor pattern 2b. Furthermore, the concave portion into which the convex portion provided in conductor pattern 2b is inserted may be provided in second joining region 3a serving as a joining surface of terminal electrode 3. Such a configuration is preferable since the positional misalignment of terminal electrode 3 can be prevented, and also, terminal electrode 3 and the main surface of conductor pattern 2b can be more firmly joined even when joined hard solder material 14 is reduced in thickness.

### REFERENCE SIGNS LIST

1 semiconductor element, 2 insulating substrate, 2a ceramic plate, 2b, 2c conductor pattern, 2d concave portion, 2e, 2f convex portion, 3 terminal electrode, 3a second joining region, 3b heating surface, 3d convex portion, 9 resin case, 12, 13 joining material (solder material), 14, 14a, 14b, 14c hard solder material, 14d, 14e concave portion, 15 roughened region, 18 contact angle, 19 light absorption film, 21 main surface, 21a first joining region, 31 laser beam.

1. A semiconductor device comprising:
a semiconductor element;
a conductor pattern provided on an insulating substrate and having a main surface to which the semiconductor element is joined; and
a terminal electrode joined to the main surface of the conductor pattern by a hard solder material and electrically connected to the semiconductor element,
a joining region joined to the hard solder material on the main surface of the conductor pattern including
a first region in which the terminal electrode exists in a plan view, and
a second region located outside the first region and not overlapping with the terminal electrode.

2. The semiconductor device according to claim 1, wherein the semiconductor element is joined to the main surface of the conductor pattern by a soft solder material.

3. The semiconductor device according to claim 1, further comprising a resin case surrounding the insulating substrate, wherein
the terminal electrode is attached to the resin case.

4. The semiconductor device according to claim 1, wherein the main surface of the conductor pattern has, in the second region, a roughened region that is greater in surface roughness than outside the joining region.

5. The semiconductor device according to claim 4, wherein
the terminal electrode includes
a first surface joined to the main surface of the conductor pattern by the hard solder material, and
a second surface provided on a back side of the first surface, and
the roughened region is greater in surface roughness than the second surface of the terminal electrode.

6. The semiconductor device according to claim 4, wherein the roughened region is provided with a metal film that is higher in absorptance of light, which has a wavelength equal to or greater than 500 nm and equal to or less than 1500 nm, than the main surface of the conductor pattern.

7. The semiconductor device according to claim 1, wherein the main surface of the conductor pattern in the second region includes a light absorption region that is higher in absorptance of light, which has a wavelength equal to or greater than 500 nm and equal to or less than 1500 nm, than the main surface of the conductor pattern outside the joining region.

8. The semiconductor device according to claim 7, wherein
the terminal electrode includes
a first surface joined to the main surface of the conductor pattern by the hard solder material, and
a second surface provided on a back side of the first surface, and
the light absorption region is higher in absorptance of light, which has a wavelength equal to or greater than 500 nm and equal to or less than 1500 nm, than the second surface of the terminal electrode.

9. The semiconductor device according to claim 1, wherein one of surfaces of the terminal electrode is a convex surface on which the terminal electrode is joined to the hard solder material.

10. The semiconductor device according to claim 1, wherein the hard solder material has a portion in which a contact angle with the terminal electrode is an acute angle.

11. A method of manufacturing a semiconductor device, the method comprising:
a first step of disposing a hard solder material on a main surface of a conductor pattern that is provided on an insulating substrate, a semiconductor element being joined to the main surface;
a second step of disposing a terminal electrode on the hard solder material; and
a third step of applying a laser beam to the terminal electrode and a surrounding region that is located on the main surface of the conductor pattern and that has the hard solder material disposed thereon, to melt the hard solder material, and join the main surface of the conductor pattern and the terminal electrode by the hard solder material.

12. The method of manufacturing a semiconductor device according to claim 11, further comprising a fourth step of joining the semiconductor element and the insulating substrate by a soft solder material.

13. The method of manufacturing a semiconductor device according to claim 11, wherein, in the second step, the terminal electrode is disposed so as to entirely cover the hard solder material in a plan view.

14. The method of manufacturing a semiconductor device according to claim 11, wherein
the conductor pattern has a convex portion on the main surface,
the hard solder material has a concave portion into which the convex portion is inserted, and
in the first step, the hard solder material is disposed on the main surface of the conductor pattern in a state where the convex portion is inserted into the concave portion.

15. The method of manufacturing a semiconductor device according to claim 11, wherein
the terminal electrode has a convex portion on a surface to be joined to the main surface of the conductor pattern,
the hard solder material has a concave portion into which the convex portion is inserted, and
in the second step, the terminal electrode is disposed on the hard solder material in a state where the convex portion is inserted into the concave portion.

16. The method of manufacturing a semiconductor device according to claim 11, wherein
the main surface of the conductor pattern to which the laser beam is applied includes a roughened region that is greater in surface roughness than the main surface of the conductor pattern outside a region to which the laser beam is applied.

17. The method of manufacturing a semiconductor device according to claim 16, wherein the roughened region is greater in surface roughness than the terminal electrode to which the laser beam is applied.

18. The method of manufacturing a semiconductor device according to claim 16, wherein a metal film is provided on the roughened region, the metal film being greater in absorptance of light having a wavelength of the laser beam than a material of the conductor pattern.

19. The method of manufacturing a semiconductor device according to claim 11, wherein
the main surface of the conductor pattern to which the laser beam is applied includes a light absorption region that is greater in absorptance of light having a wavelength of the laser beam than the main surface of the conductor pattern outside a region to which the laser beam is applied.

20. The method of manufacturing a semiconductor device according to claim 19, wherein the light absorption region is greater in absorptance of light having the wavelength of the laser beam than a surface of the terminal electrode in the region to which the laser beam is applied.
